(19) United States
(12) Patent Application Publication
(10) Pub. No.: US 2017/0276694 A1
(43) Pub. Date: Sep. 28, 2017

(54) CIRCUIT DEVICE, PHYSICAL QUANTITY DETECTION DEVICE, ELECTRONIC APPARATUS, AND VEHICLE

(71) Applicant: SEIKO EPSON CORPORATION, Tokyo (JP)

(72) Inventor: Jun UEHARA, Fujimi-machi (JP)

(73) Assignee: SEIKO EPSON CORPORATION, Tokyo (JP)

(21) Appl. No.: 15/454,231

(22) Filed: Mar. 9, 2017

(30) Foreign Application Priority Data
Mar. 25, 2016 (JP) 2016-061314

(51) Int. Cl. G01P 3/00; G05F 3/02; H03M 1/12; H03H 7/06; G01P 15/00

(52) U.S. Cl. CPC G01P 3/00; H03H 7/06; G01P 15/00; H03M 1/122; G05F 3/02

(57) ABSTRACT

A circuit device includes first and second detection circuits which detect physical quantity signals based on detection signals from first and second physical quantity transducers, a multiplexer which selects any one signal among a plurality of signals including the physical quantity signals from the first and second detection circuits, an A/D conversion circuit which performs A/D conversion of the selected signal, and a logic circuit which performs processing of a digital signal from the A/D conversion circuit. The first detection circuit is arranged on a second direction side from a first side of the circuit device. The second detection circuit is arranged on the second direction side from the first side and on a first direction side from the first detection circuit. The A/D conversion circuit is arranged between at least one of the first or second detection circuit and the logic circuit.

### BACKGROUND

1. Technical Field

The present invention relates to a circuit device, a physical quantity detection device, an electronic apparatus, a vehicle, and the like.

2. Related Art

A physical quantity detection device which detects a physical quantity based on a detection signal from a physical quantity transducer is hitherto known. Taking a gyro sensor as an example, an angular velocity or the like is detected as a physical quantity. A gyro sensor is incorporated in, for example, an electronic apparatus, such as a digital camera or a smartphone, or a vehicle, such as an automobile or an airplane, and camera shake correction, posture control, GPS autonomous navigation, or the like is performed using the detected physical quantity, such as an angular velocity.

An example of the related art of such a physical quantity detection device is a technique disclosed in JP-A-2010-203990. JP-A-2010-203990 discloses a composite sensor which is provided with a vibration type angular velocity sensor element formed on a substrate, an acceleration sensor element formed on the substrate, and a package.

Like the composite sensor of JP-A-2010-203990, a physical quantity detection device in which a plurality of physical quantity transducers are provided has the following problems.

For example, if a signal path through which the detection signals from the first and second physical quantity transducers are input to a detection circuit in a circuit device (IC chip) is long, since a detection signal of a weak signal (current signal or the like) flows in a wiring of the signal path, characteristics may be deteriorated due to noise superimposition or the like.

It is assumed that a first circuit block which processes a detection signal of a weak signal and a second circuit block which treats a signal having comparatively large voltage amplitude are arranged close to each other in a circuit device. The first circuit block is a detection circuit to which, for example, the detection signal from the physical quantity transducer is input. The second circuit block is a logic circuit which performs processing of a digital signal obtained through A/D conversion of an output signal of the detection circuit. In this case, noise from the second circuit block (logic circuit) is routed to the first circuit block (detection circuit), and accordingly, the detection characteristics, output characteristics, or the like of the first circuit block may be deteriorated.

It is assumed that a plurality of detection circuits corresponding to a plurality of physical quantity transducers are provided in a circuit device. In this case, a multiplexer which selects any one of a plurality of physical quantity signals from a plurality of detection circuits, an A/D conversion circuit which performs A/D conversion of the signal selected by the multiplexer, and the like are required. There is a problem in that the circuit device increases in size, or the like according to a location where the multiplexer or the A/D conversion circuit is arranged.

### SUMMARY

An advantage of some aspects of the invention is to provide a circuit device, a physical quantity detection device, an electronic apparatus, a vehicle, and the like capable of reducing characteristic deterioration or the like in a case where a plurality of detection circuits corresponding to a plurality of physical quantity transducers are provided.

The advantage can be achieved by the following configurations.

A circuit device according to an aspect of the invention includes a first detection circuit which detects a first physical quantity signal corresponding to a first physical quantity based on a first detection signal from a first physical quantity transducer, a second detection circuit which detects a second physical quantity signal corresponding to a second physical quantity based on a second detection signal from a second physical quantity transducer, a multiplexer which selects any one signal among a plurality of signals including the first physical quantity signal from the first detection circuit and the second physical quantity signal from the second detection circuit, an A/D conversion circuit which performs A/D conversion of the signal selected by the multiplexer to output a digital signal, and a logic circuit which performs processing of the digital signal from the A/D conversion circuit. In a case where a direction along a first side of the circuit device is defined as a first direction and a direction from the first side toward a second side opposite to the first side is defined as a second direction, the first detection circuit is arranged on the second direction side from the first side, the second detection circuit is arranged on the second direction side from the first side and on the first direction side from the first detection circuit, and the A/D conversion circuit is arranged between at least one of the first detection circuit or the second detection circuit and the logic circuit.

In the aspect of the invention, the first and second detection circuits corresponding to the first and second physical quantity transducers are provided, any one of a plurality of signals including the first and second physical quantity signals from the first and second detection circuits is selected by the multiplexer, and A/D conversion of the selected signal is performed. The first detection circuit is arranged on the second direction side from the first side of the circuit device, and the second detection circuit is arranged on the second direction side from the first side and on the first direction side from the first detection circuit. The A/D conversion circuit is arranged between at least one of the first or second detection circuit and the logic circuit. With this, in a case where the first and second physical quantity transducers are arranged at the locations corresponding to the first and second detection circuits, it is possible to optimize a signal path between the first and second detection circuits and the first and second physical quantity transducers, and reduction of characteristic deterioration or the like is achieved. It is possible to arrange the logic circuit to be a noise source at a position separated from the circuit block which processes a weak detection signal, and to reduce characteristic deterioration or the like due to the noise source. Therefore, it is possible to provide a circuit device capable of reducing characteristic deterioration in a case where a plurality of detection circuits corresponding to a plurality of physical quantity transducers are provided.

In the aspect of the invention, the multiplexer may be arranged between at least one of the first detection circuit or the second detection circuit and the logic circuit.

With this configuration, it is also possible to optimize a signal path between the first and second detection circuits and the multiplexer, and to reduce deterioration of the first and second physical quantity signals from the first and second detection circuits due to signal transmission or the like through the signal path.

In the aspect of the invention, in a case where a direction opposite to the first direction is defined as a third direction, the A/D conversion circuit may be arranged on the third direction side or the first direction side from the multiplexer.

With this configuration, it is possible to optimize a signal path between the multiplexer and the A/D conversion circuit, and to reduce deterioration of the signal from the multiplexer due to signal transmission or the like through the signal path.

In the aspect of the invention, the circuit device may further include a power supply circuit which supplies a power supply voltage, in a case where the A/D conversion circuit is arranged on the third direction side from the multiplexer, the power supply circuit may be arranged on the first direction side from the multiplexer, and in a case where the A/D conversion circuit is arranged on the first direction side from the multiplexer, the power supply circuit may be arranged on the third direction side from the multiplexer.

If the power supply circuit is arranged in this way, it is possible to optimally wire a power line between the power supply circuit and each circuit block of the circuit device, and to achieve improvement of wiring efficiency of the power line, optimization of impedance of power supply, or the like.

In the aspect of the invention, in a case where a direction opposite to the second direction is defined as a fourth direction, the logic circuit may be arranged on the fourth direction side from the second side and on the second direction side from at least one of the first detection circuit or the second detection circuit.

With this configuration, it is possible to separate the logic circuit to be a noise source from an analog circuit which handles a weak signal, or the like. With this, it is possible to effectively reduce characteristic deterioration or the like of an analog circuit due to noise from the logic circuit.

In the aspect of the invention, the circuit device may further include a first low-pass filter which performs low-pass filter processing of the first physical quantity signal, and the first low-pass filter may be arranged between the first detection circuit and the multiplexer.

With this configuration, it is possible to transmit a signal, which is input from the first detection circuit to the first low-pass filter, to the multiplexer in a short path.

In the aspect of the invention, the circuit device may further include a second low-pass filter which performs low-pass filter processing of the second physical quantity signal, and the second low-pass filter is arranged between the second detection circuit and the multiplexer.

With this configuration, it is possible to transmit a signal, which is input from the second detection circuit to the second low-pass filter, to the multiplexer in a short path.

In the aspect of the invention, in a case where a side intersecting the first side and the second side is defined as a third side, a side intersecting the first side and the second side and opposite to the third side is defined as a fourth side, an area of the circuit device divided by a boundary line parallel to the third side and the fourth side and the third side is defined as a first area, and an area of the circuit device divided by the boundary line and the fourth side is defined as a second area, the first detection circuit may be arranged in the first area, and the second detection circuit may be arranged in the second area.

With this configuration, for example, in a case where the first physical quantity transducer is arranged at a location corresponding to the first area of the circuit device, and the second physical quantity transducer is arranged at a location corresponding to the second area, it is possible to optimize the signal path through the first and second detection circuits and the first and second physical quantity transducers, and reduction of characteristic deterioration or the like is achieved.

In the aspect of the invention, the circuit device may further include a first drive circuit which drives the first physical quantity transducer, and the first drive circuit may be arranged in the first area.

With this configuration, in a case where the first physical quantity transducer is arranged at a location corresponding to the first area of the circuit device, it is possible to optimize a signal path between the first drive circuit and the first physical quantity transducer, and to enable efficient drive of the first physical quantity transducer.

In the aspect of the invention, the first drive circuit may be arranged between the third side and the logic circuit or between the second side and the logic circuit.

With this configuration, for example, it is possible to arrange the first drive circuit at a location separated from the first detection circuit or the like, and to reduce an adverse effect of noise generated in the first drive circuit on the characteristics or the like of the first detection circuit.

In the aspect of the invention, the A/D conversion circuit may be arranged in the first area.

With this configuration, for example, it is possible to approach the distance between the first detection circuit and the A/D conversion circuit, or the like, and to input a signal from the first detection circuit to the A/D conversion circuit in a short path.

In the aspect of the invention, the circuit device may further include a master clock signal generation circuit which generates a master clock signal, and the master clock signal generation circuit may be arranged in the second area.

With this configuration, it is possible to effectively reduce an adverse effect of noise from the master clock signal generation circuit on the characteristics or the like of an analog circuit arranged in the first area.

In the aspect of the invention, the circuit device may further include a digital interface circuit which performs at least one of an input or an output of a digital signal, and the digital interface circuit may be arranged between the logic circuit and the second side.

With this configuration, it is possible to separate the distance between the digital interface circuit and an analog system circuit, and to reduce characteristic deterioration or the like of an analog system circuit due to noise from the digital interface circuit.

In the aspect of the invention, the first physical quantity may be an angular velocity around a predetermined axis, and the second physical quantity may be an angular velocity around an axis different from the predetermined axis.

With this configuration, it is possible to implement a composite sensor capable of detecting angular velocities around a plurality of axes.

In the aspect of the invention, the first physical quantity may be an angular velocity, and the second physical quantity may be an acceleration.

With this configuration, it is possible to implement a composite sensor capable of detecting both of an angular velocity and an acceleration.

A physical quantity detection device according to another aspect of the invention includes the circuit device described above, the first physical quantity transducer, and the second physical quantity transducer.

An electronic apparatus according to another aspect of the invention includes the circuit device described above.

A vehicle according to another aspect of the invention includes the circuit device described above.

### BRIEF DESCRIPTION OF THE DRAWINGS

The invention will be described with reference to the accompanying drawings, wherein like numbers reference like elements.

FIG. 1 shows a configuration example of a circuit device of this embodiment.

FIG. 2 shows an arrangement configuration example of circuit blocks of the circuit device.

FIG. 3 shows another arrangement configuration example of the circuit blocks of the circuit device.

FIG. 4 is a plan view showing an example of a physical quantity detection device of this embodiment.

FIG. 5 is a sectional view of the physical quantity detection device taken along the line A-A of FIG. 4.

FIG. 6 is a sectional view of the physical quantity detection device taken along the line B-B of FIG. 4.

FIG. 7 is an operation explanatory view of an angular velocity sensor for a Z axis.

FIG. 8 is an operation explanatory view of an angular velocity sensor for an X axis.

FIG. 9 is an operation explanatory view of the angular velocity sensor for an X axis.

FIG. 10 shows a detailed configuration example of the circuit device of this embodiment.

FIG. 11 shows an arrangement configuration example of circuit blocks of the circuit device.

FIG. 12 is an explanatory view of an arrangement method of the circuit blocks of this embodiment.

FIG. 13 is an explanatory view of an arrangement method of the circuit blocks of this embodiment.

FIG. 14 shows a configuration example of a drive circuit and a detection circuit.

FIG. 15 shows a configuration example of a low-pass filter.

FIG. 16 shows a configuration example of an A/D conversion circuit and a multiplexer.

FIG. 17 shows a configuration example of a master clock signal generation circuit.

FIG. 18 shows a configuration example of a digital I/F circuit.

FIG. 19 shows a configuration example of a power supply circuit.

FIG. 20 shows a configuration example of an acceleration sensor and a second detection circuit for an acceleration sensor.

FIG. 21 shows an example of a vehicle in which the circuit device of this embodiment is incorporated.

FIG. 22 shows an example of an electronic apparatus in which the circuit device of this embodiment is incorporated.

FIG. 23 shows an example of an electronic apparatus in which the circuit device of this embodiment is incorporated.

FIG. 24 shows an example of a vehicle (electronic apparatus) in which the circuit device of this embodiment is incorporated.

### DESCRIPTION OF EXEMPLARY EMBODIMENTS

Hereinafter, an exemplary embodiment of the invention will be described in detail. It should be noted that this embodiment described hereinafter is not intended to limit the content of the invention as described in the appended claims in any way, and not all of the configurations described in this embodiment are required as the means for solving the problems as described above.

### 1. Circuit Device

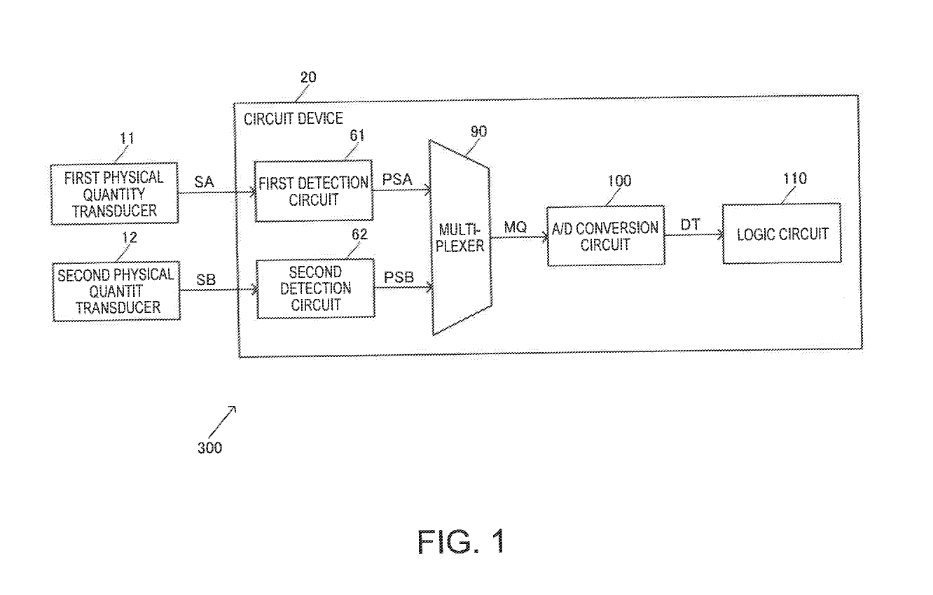

FIG. 1 shows a configuration example of a circuit device 20 of this embodiment. As shown in FIG. 1, the circuit device 20 of this embodiment includes first and second detection circuits 61 and 62, a multiplexer 90, an A/D conversion circuit 100, and a logic circuit 110. A physical quantity detection device 300 (composite sensor or a physical quantity detection sensor) of this embodiment includes first and second physical quantity transducers 11 and 12 and a circuit device 20. It should be noted that the circuit device 20 and the physical quantity detection device 300 are not limited to the configurations of FIG. 1, and may be modified in various ways such that a part of the constituent elements may be omitted, other constituent elements may be added, or the like.

The first detection circuit 61 detects a first physical quantity signal PSA (first desired signal) corresponding to a first physical quantity based on a first detection signal SA (first sensor signal) from the first physical quantity transducer 11. Then, the first detection circuit 61 outputs the detected first physical quantity signal PSA. The second detection circuit 62 detects a second physical quantity signal PSB (second desired signal) corresponding to a second physical quantity based on a second detection signal SB (second sensor signal) from the second physical quantity transducer 12. Then, the second detection circuit 62 outputs the detected second physical quantity signal PSB. The first and second detection signals SA and SB are, for example, analog electric signals, such as a current signal or a voltage signal. The first and second physical quantity signals PSA and PSB are also analog electric signals, such as a voltage signal. Each of the first and second detection signals SA and SB or each of the first and second physical quantity signals PSA and PSB may be a differential signal or may be a single end signal.

The multiplexer 90 selects any one signal among a plurality of signals including the first physical quantity signal PSA from the first detection circuit 61 and the second physical quantity signal PBS from the second detection circuit 62. Then, the multiplexer 90 outputs the selected signal as a signal MQ. The multiplexer 90 is constituted of, for example, a plurality of switching elements, and each switching element is implemented with a MOS transistor or the like.

In FIG. 1, although only the first and second physical quantity signals PSA and PSB are input to the multiplexer 90, signals other than PSA and PSB may be input. For example, in addition to the first and second detection circuits 61 and 62, one or a plurality of detection circuits which detect other physical quantity signals may be provided, and physical quantity signals from other detection circuits may be input to the multiplexer 90. A temperature detection signal from a temperature sensor, or the like may be input to the multiplexer 90.

The A/D conversion circuit 100 performs A/D conversion of the signal MQ selected by the multiplexer 90 and outputs a digital signal DT. That is, the A/D conversion circuit 100 outputs the digital signal DT obtained by A/D converting the analog signal MQ. The signal is selected by the multiplexer 90 and A/D conversion of the selected signal is performed, whereby it is possible to perform time-division A/D conversion on a plurality of respective signals input to the multiplexer 90.

As the A/D conversion circuit 100, for example, various types of A/D conversion circuits, for example, a successive comparison type and a delta-sigma type, can be employed. For example, in a case where a delta-sigma type is employed, for example, an A/D conversion circuit which has a function of correlated double sampling (CDS), a chopper, or the like for 1/f noise reduction and is constituted of, for example, a second-order delta-sigma modulator or the like can be used. In a case where a successive comparison type is employed, for example, an A/D conversion circuit which has a function of dynamic element matching (DEM) or the like to reduce deterioration of an S/N ratio due to element variation of DACs, and is constituted of a capacitive DAC and a successive comparison control block can be used. The A/D conversion circuit 100 may include a programmable gain amplifier (PGA) which adjusts the gain of the signal MQ, or the like.

The logic circuit 110 performs processing of the digital signal DT from the A/D conversion circuit 100. For example, the logic circuit 110 (DSP unit) performs various kinds of digital signal processing on the digital signal DT. For example, the logic circuit 110 performs digital filter processing or digital correction processing on the digital signal DT from the A/D conversion circuit 100. The digital filter processing is, for example, digital filter processing of band limiting according to an application of a desired signal or digital filter processing for removing noise generated in the A/D conversion circuit 100 or the like. The digital correction processing is, for example, zero-point correction processing (offset correction), sensitivity correction processing (gain correction), or the like. Furthermore, the logic circuit 110 performs various kinds of control processing of the circuit device 20. For example, the logic circuit 110 performs control processing of each circuit block of the circuit device 20, or the like. The logic circuit 110 can be implemented with, for example, a circuit of automatic arrangement and wiring, such as a gate array circuit.

In FIG. 1, the first physical quantity is, for example, an angular velocity around a predetermined axis, and the second physical quantity is an angular velocity around an axis different from the predetermined axis. The predetermined axis (for example, a first axis) is one axis among an X axis, a Y axis, and a Z axis, and the axis (for example, a second axis) different from the predetermined axis is an axis different from one axis among the X axis, the Y axis, and the Z axis. In this case, the first and second physical quantity transducers 11 and 12 become angular velocity sensors (gyro sensor). Then, the first and second detection circuits 61 and 62 detect and output the first and second physical quantity signals PSA and PSB as angular velocity signals based on the detection signals (current signals or electric charge signals) from the first and second physical quantity transducers 11 and 12 as angular velocity sensors. With this, for example, the angular velocities around a plurality of axes, such as the first axis and the second axis, can be detected using the circuit device 20. A detection circuit which detects an angular velocity around a third axis different from the first axis and the second axis may be further provided in the circuit device 20.

The first physical quantity may be an angular velocity, and the second physical quantity may be an acceleration. In this case, the first physical quantity transducer 11 becomes an angular velocity sensor (gyro sensor), and the second physical quantity transducer 12 becomes an acceleration sensor. Then, the first detection circuit 61 detects and outputs the first physical quantity signal PSA as an angular velocity signal based on the detection signal from the first physical quantity transducer 11 as an angular velocity sensor. The second detection circuit 62 detects and outputs the second physical quantity signal PSB as an acceleration signal based on the detection signal from the second physical quantity transducer 12 as an acceleration sensor. With this, the angular velocity around a predetermined axis (first, second, or third axis) can be detected and the acceleration in the predetermined axis direction (first, second, or third axis direction) can be detected using the circuit device 20.

The configurations of the circuit device 20 and the physical quantity detection device 300 can be modified in various ways. For example, in FIG. 1, although a configuration in which the two detection circuits (61 and 62) corresponding to the two physical quantity transducers (11 and 12) are provided has been shown, a modification in which detection circuits corresponding to three or more physical quantity transducers are provided may be made. For example, in a case where each physical quantity transducer is an angular velocity sensor, detection circuits corresponding to angular velocity sensors around a plurality of axes may be provided. An angular velocity sensor may be a piezoelectric vibration gyro or a static capacitance detection type vibration gyro formed of a silicon substrate or the like. In a case where each physical quantity transducer is an acceleration sensor, detection circuits corresponding to acceleration sensors in a plurality of axis directions may be provided. Each physical quantity transducer may detect angular velocities around a plurality of axes or may detect accelerations in a plurality of axis directions. Each physical quantity transducer may be a transducer which detects a physical quantity (for example, speed, moving distance, angular acceleration, pressure, or the like) other than an angular velocity or an acceleration.

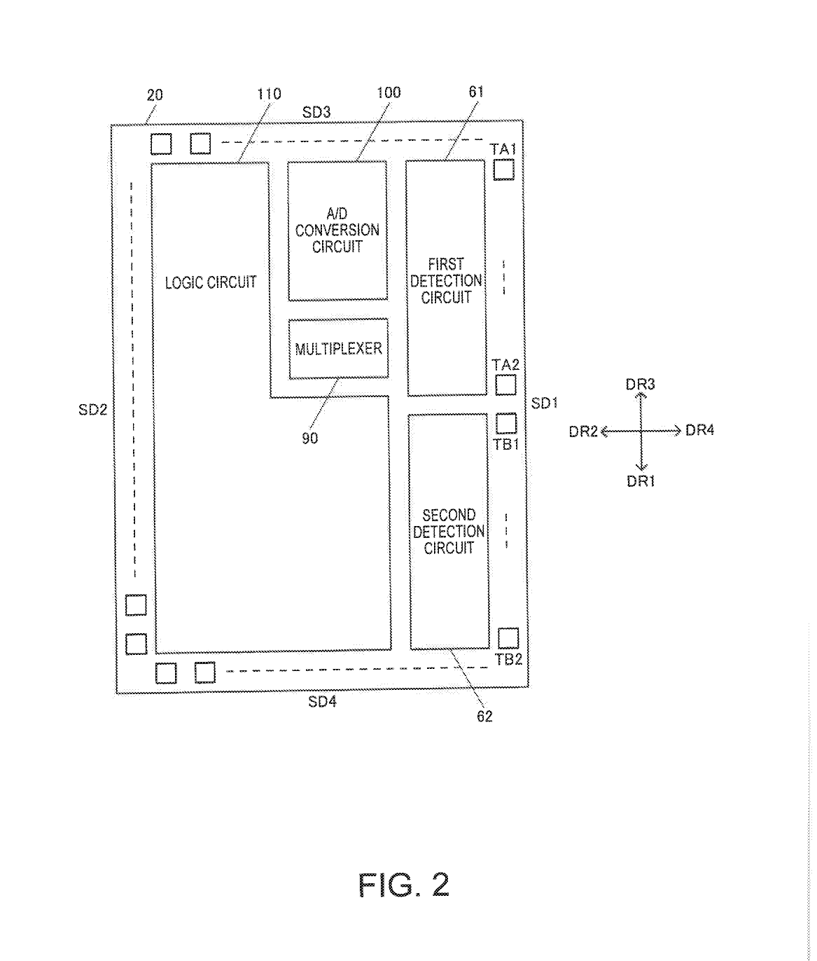

FIG. 2 shows an arrangement configuration example of circuit blocks of the circuit device 20 of this embodiment. FIG. 2 is a diagram showing a layout arrangement of a semiconductor chip of the circuit device 20.

The circuit device 20 (semiconductor chip) has first, second, third, and fourth sides (side edges) SD1, SD2, SD3, and SD4. A side opposite to the first side SD1 is the second side SD2. The third and fourth sides SD3 and SD4 are sides intersecting (orthogonal to) the first and second sides SD1 and SD2, and a side opposite to the third side SD3 is the fourth side SD4. In FIG. 2, a direction along the first side SD1 of the circuit device 20 is defined as a first direction DR1, and a direction from the first side SD1 toward the second side SD2 opposite to the first side SD1 is defined as a second direction DR2. The second direction DR2 is a direction intersecting (orthogonal to) the first direction DR1. A direction opposite to the first direction DR1 is defined as a third direction DR3, and a direction opposite to the second direction DR2 is defined as a fourth direction DR4.

In this case, the first detection circuit 61 is arranged on the second direction DR2 side from the first side SD1 of the circuit device 20. For example, the first detection circuit 61 is arranged along the first direction DR1 in an area (an area having a predetermined width) on the second direction DR2 side from the first side SD1. For example, the first detection circuit 61 is arranged such that the first direction DR1 becomes a long-side direction.

The second detection circuit 62 is arranged on the second direction DR2 side from the first side SD1 and on the first direction DR1 side from the first detection circuit 61. In FIG. 2, the second detection circuit 62 is arranged adjacent to the first detection circuit 61 on the first direction DR1 side from the first detection circuit 61. For example, the second detection circuit 62 is arranged along the first direction DR1 in an area (an area having a predetermined width) on the second direction DR2 side from the first side SD1. For example, the second detection circuit 62 is arranged such that the first direction DR1 becomes a long-side direction.

The A/D conversion circuit 100 is arranged between at least one of the first detection circuit 61 or the second detection circuit 62 and the logic circuit 110. For example, in FIG. 2, the A/D conversion circuit 100 is arranged between the first detection circuit 61 and the logic circuit 110. That is, the A/D conversion circuit 100 is arranged on the second direction DR2 side from the first detection circuit 61, and the logic circuit 110 is arranged on the second direction DR2 side from the A/D conversion circuit 100. The A/D conversion circuit 100 may be arranged between the second detection circuit 62 and the logic circuit 110. That is, the A/D conversion circuit 100 may be arranged on the second direction DR2 side from the second detection circuit 62. Alternatively, the A/D conversion circuit 100 may be arranged between both of the first and second detection circuits 61 and 62 and the logic circuit 110.

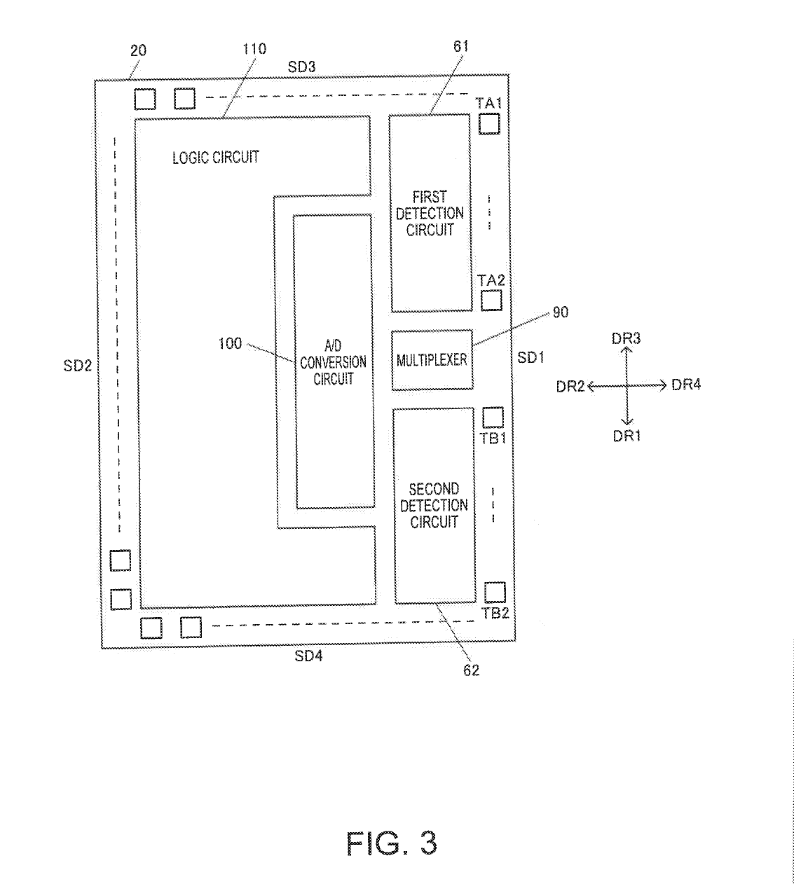

For example, FIG. 3 shows another arrangement configuration example (layout arrangement example) of the circuit device 20 of this embodiment. In FIG. 3, the A/D conversion circuit 100 is arranged between both of the first and second detection circuits 61 and 62 and the logic circuit 110. That is, the A/D conversion circuit 100 is arranged on the second direction DR2 side of both of the first and second detection circuits 61 and 62.

In this embodiment, the multiplexer 90 is arranged between at least one of the first detection circuit 61 or the second detection circuit 62 and the logic circuit 110. For example, in FIG. 2, the multiplexer 90 is arranged between the first detection circuit 61 and the logic circuit 110. That is, the multiplexer 90 is arranged on the second direction DR2 side from the first detection circuit 61, and the logic circuit 110 is arranged on the second direction DR2 side from the multiplexer 90. The multiplexer 90 may be arranged between the second detection circuit 62 and the logic circuit 110. That is, the multiplexer 90 may be arranged on the second direction DR2 side from the second detection circuit 62. Alternatively, the multiplexer 90 may be arranged between both of the first and second detection circuits 61 and 62 and the logic circuit 110. Alternatively, as shown in another arrangement configuration example of FIG. 3, the multiplexer 90 may be arranged between the first detection circuit 61 and the second detection circuit 62.

In this embodiment, in a case where the direction opposite to the first direction DR1 is defined as the third direction DR3, the A/D conversion circuit 100 is arranged on the third direction DR3 side or the first direction DR1 side from the multiplexer 90. For example, in FIG. 2, the A/D conversion circuit 100 is arranged on the third direction DR3 side from the multiplexer 90. Alternatively, the A/D conversion circuit 100 may be arranged on the first direction DR1 side from the multiplexer 90. In another arrangement example of FIG. 3, the A/D conversion circuit 100 is arranged on the second direction DR2 side from the multiplexer 90.

In this embodiment, in a case where the direction opposite to the second direction DR2 is defined as the fourth direction DR4, the logic circuit 110 is arranged on the fourth direction DR4 side from the second side SD2 and on the second direction DR2 side from at least one of the first detection circuit 61 or the second detection circuit 62. For example, in FIGS. 2 and 3, the logic circuit 110 is arranged on the fourth direction DR4 side from the second side SD2 and on the second direction DR2 side of both of the first and second detection circuits 61 and 62. The logic circuit 110 may be arranged only on the second direction DR2 side of the first detection circuit 61 or may be arranged only on the second direction DR2 side of the second detection circuit 62.

In FIGS. 2 and 3, the logic circuit 110 is arranged adjacently to the fourth direction DR4 side of an I/O area (pad arrangement area) along the second side SD2. The I/O area is an area where at least one of a pad, an I/O circuit, or a protection circuit (electrostatic protection or the like) is arranged. For example, the logic circuit 110 is arranged such that the long side of the logic circuit 110 on the second direction DR2 side is along the long side of the I/O area. In the I/O area, for example, a pad (in a broad sense, a terminal) for the logic circuit 110, or the like is arranged.

The first and second detection circuits 61 and 62 are arranged adjacently to the second direction DR2 side of an I/O area (pad arrangement area) along the first side SD1. For example, the first and second detection circuits 61 and 62 are arranged such that the long sides of the first and second detection circuits 61 and 62 on the fourth direction DR4 side are along the long side of the I/O area. In the I/O area, pads TA1 and TA2 for the first detection circuit 61, or pads TB1 and TB2 for the second detection circuit 62 are arranged. For example, the detection signal SA (differential detection signal) of FIG. 1 is input to the first detection circuit 61 through the pads TA1 and TA2 (terminals). The detection signal SB (differential detection signal) is input to the second detection circuit 62 through the pads TB1 and TB2 (terminals).

As described above, in this embodiment, the first detection circuit 61 is arranged on the second direction DR2 side from the first side SD1 of the circuit device 20, and the second detection circuit 62 is arranged on the second direction DR2 side from the first side SD1 and the first direction DR1 side from the first detection circuit 61. That is, the first and second detection circuits 61 and 62 are arranged along the first direction DR1 on the second direction DR2 side of the first side SD1. Therefore, it is possible to implement a first signal path (first signal wiring) between the first physical quantity transducer 11 and the first detection circuit 61 or a second signal path (second signal wiring) between the second physical quantity transducer 12 and the second detection circuit 62 of FIG. 1 with a signal path of a short wiring.

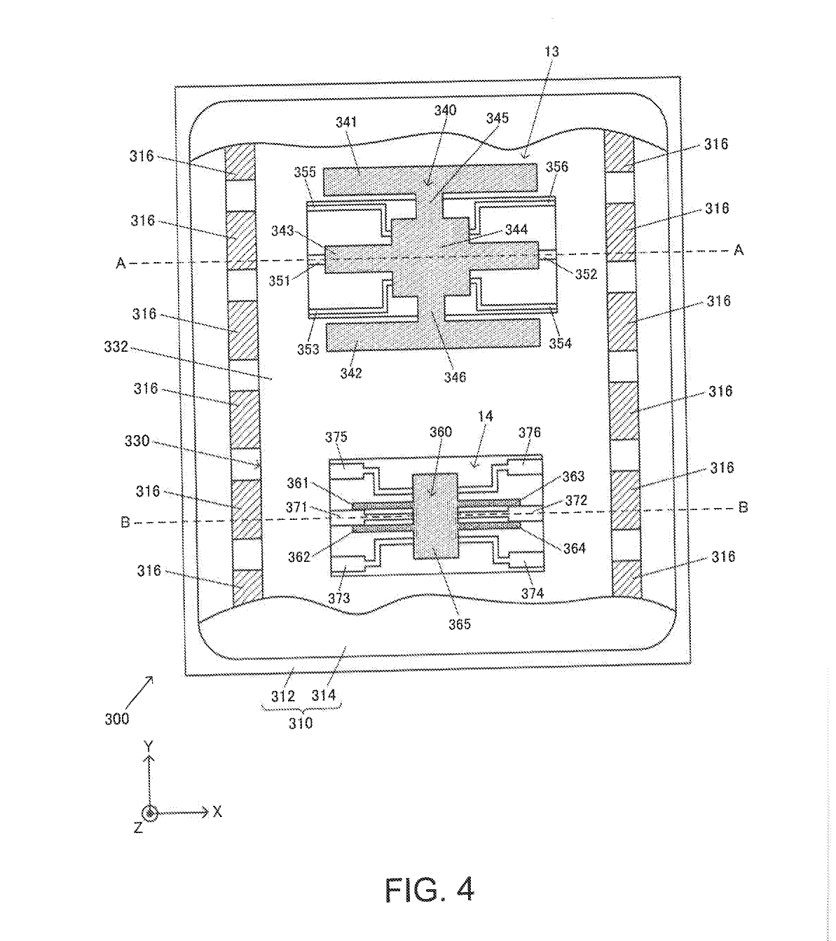

For example, in the physical quantity detection device 300 of FIGS. 4 to 6 described below, the first physical quantity transducer 11 (for example, an angular velocity sensor for a Z axis) is arranged above (an upper side in a vertical direction of) the first detection circuit 61, and the second physical quantity transducer 12 (for example, an angular velocity sensor for an X axis) is arranged above the second detection circuit 62. In a case of such an arrangement configuration, as in FIGS. 2 and 3, if the first and second detection circuits 61 and 62 are arranged along the first direction DR1 on the second direction DR2 side of the first side SD1, it is possible to implement the first and second signal paths between the first and second physical quantity transducers 11 and 12 and the first and second detection circuits 61 and 62 with short signal paths. In the first and second signal paths, since a signal (current signal) having weak amplitude is transmitted, if a wiring of a signal path is extended, noise may be superimposed and the detection characteristics or the like of the first and second detection circuits 61 and 62 may be deteriorated. From this, according to the arrangement configuration of this embodiment, since it is possible to make the first and second signal paths into signal paths of short wirings, it is possible to reduce characteristic deterioration due to noise or the like.

In this embodiment, since the A/D conversion circuit 100 is arranged between at least one of the first or second detection circuit 61 or 62 and the logic circuit 110, it is possible to arrange the logic circuit 110 on the second side SD2 side. Accordingly, it is possible to arrange the logic circuit 110 to be a noise source at a position separated from at least one of the first or second detection circuit, 61 or 62. Hence, it is possible to effectively reduce deterioration of analog characteristics due to transmission of noise from the logic circuit 110 to an analog system circuit which handles a weak signal, such as the first and second detection circuits 61 and 62. Therefore, it is possible to provide the circuit device 20 capable of reducing characteristic deterioration or the like in a case where a plurality of detection circuits corresponding to a plurality of physical quantity transducers are provided.

In this embodiment, the A/D conversion circuit 100 is arranged between at least one of the first or second detection circuit, 61 or 62, and the logic circuit 110. With this, since it is possible to arrange the A/D conversion circuit 100 by effectively utilizing an area between at least one of the first or second detection circuit, 61 or 62, and the logic circuit 110, it is possible to improve layout efficiency, and reduction in scale (reduction in area) of the circuit device 20 is achieved. Therefore, it is also possible to achieve both of reduction in characteristic deterioration and reduction in scale of the circuit device 20.

In this embodiment, the multiplexer 90 is arranged between at least one of the first or second detection circuit, 61 or 62, and the logic circuit 110. With this, it is possible to make a third signal path between the first detection circuit 61 and the multiplexer 90 or a fourth signal path between the second detection circuit 62 and the multiplexer 90 into a short signal path. Therefore, it is possible to reduce deterioration of the first and second physical quantity signals PSA and PSB from the first and second detection circuits 61 and 62 due to signal transmission through the third and fourth signal paths, and reduction of deterioration of signal characteristics is achieved.

In this embodiment, the A/D conversion circuit 100 is arranged on the third direction DR3 side or the first direction DR1 side from the multiplexer 90. For example, the A/D conversion circuit 100 is arranged adjacently to the multiplexer 90. With this, it is possible to make a fifth signal path between the multiplexer 90 and the A/D conversion circuit 100 into a short signal path. Therefore, it is possible to reduce deterioration of the signal MQ from the multiplexer 90 due to signal transmission through the fifth signal path, and reduction of deterioration of signal characteristics is achieved. For example, the multiplexer 90 is a signal selection circuit, and the output impedance of the signal MQ becomes high. Accordingly, if the fifth signal path through which the signal MQ is transmitted becomes a long wiring, noise may be superimposed on the signal and the signal characteristics may be deteriorated. From this, according to this embodiment, since it is possible to implement the fifth signal path with a short wiring, it is possible to effectively reduce deterioration of the signal characteristics.

In this embodiment, the logic circuit 110 is arranged on the fourth direction DR4 side from the second side SD2 and on the second direction DR2 side from at least one of the first or second detection circuit, 61 or 62. That is, it is possible to arrange the logic circuit 110 at a position closer to the second side SD2 than the first side SD1. Therefore, it is possible to separate the logic circuit 110 to be a noise source from a circuit, which handles a weak signal, such as the first and second detection circuits 61 and 62, as possible. For example, the logic circuit 110 is arranged on the second side SD2 side, whereby it is possible to arrange, for example, a logic system circuit on the second side SD2 side and to arrange the analog system circuit on the first side SD1 side opposite to the second side SD2. Therefore, it is possible to effectively reduce characteristic deterioration of the analog system circuit due to noise from the logic circuit 110.

### 2. Physical Quantity Detection Device

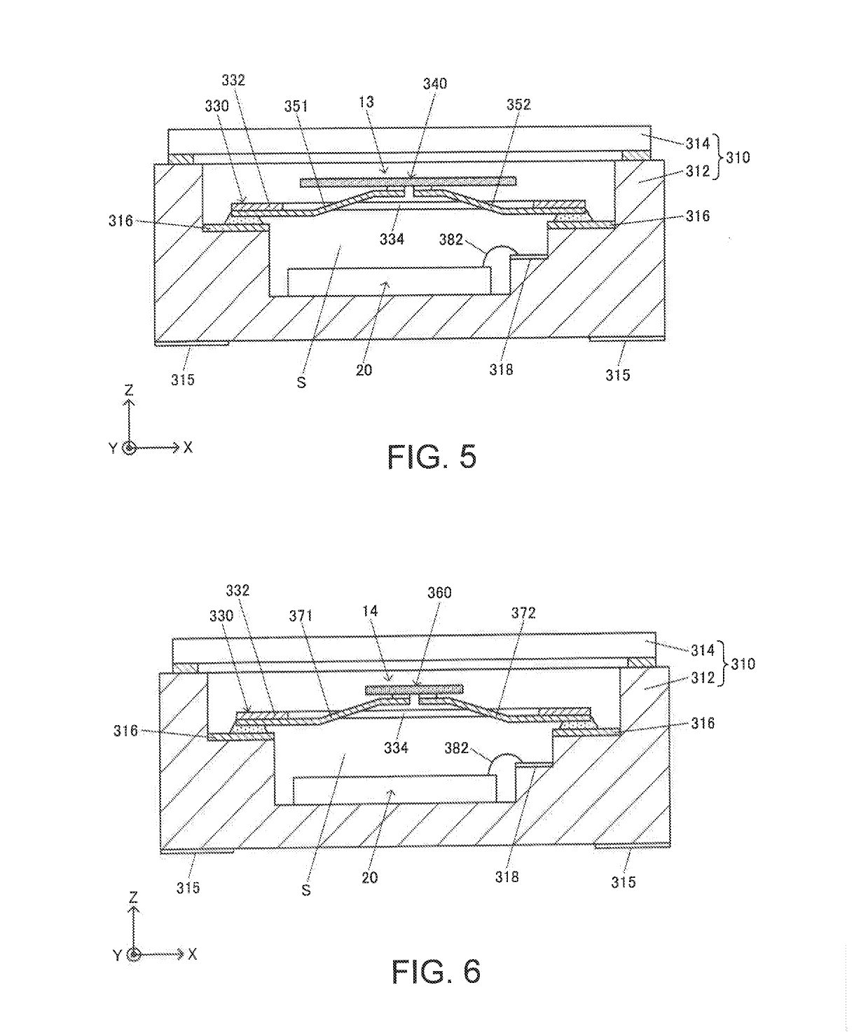

Next, an example of the physical quantity detection device 300 (composite sensor) of this embodiment will be described. FIG. 4 is a plan view of an example of the physical quantity detection device 300 of this embodiment. FIG. 5 is a sectional view of the physical quantity detection device 300 taken along the line A-A of FIG. 4, and FIG. 6 is a sectional view taken along the line B-B.

The physical quantity detection device 300 includes angular velocity sensors 13 and 14 and a package 310. The package 310 has a base 312 and a lid 314. The base 312 is a cavity-shaped member which has a recess portion opened on the top surface thereof. The lid 314 is a member which is bonded to the base 312 to close the opening of the recess portion of the base 312.

The angular velocity sensor 13 is, for example, a sensor which detects an angular velocity around the Z axis, and the angular velocity sensor 14 is, for example, a sensor which detects an angular velocity around the X axis. Here, three axes (first, second, and third axes) orthogonal to one another are referred to as the X axis, the Y axis, and the Z axis. The Z axis is an axis along a vertical direction (a direction perpendicular to the paper) in plan view of FIG. 4, and is an axis along a direction orthogonal to the lid 314. The X axis and the Y axis are axes orthogonal to the Z axis.

The angular velocity sensors 13 and 14 are respectively constituted of vibrator elements 340 and 360. The vibrator elements 340 and 360 have spread on a plane specified by a crystal axis and an electrical axis of a quartz crystal substrate, and are made in a plate shape having a thickness in an optical axis direction. Vibrators implemented with the respective vibrator elements 340 and 360 are, for example, a thickness-shear vibration type quartz crystal vibrator, such as an AT cut type or an SC cut type, or a piezoelectric vibrator, such as a flexural vibration type. As the vibrator, a surface acoustic wave (SAW) resonator as a piezoelectric vibrator, a micro electro mechanical systems (MEMS) vibrator as a silicon vibrator, or the like may be employed. As a material of the substrate of the vibrator (vibrator element), a piezoelectric material including piezoelectric single-crystal, such as quartz crystal, lithium tantalate, or lithium niobate, or piezoelectric ceramics, such as lead zirconate titanate, a silicon semiconductor, or the like can be used. As excitation means of the vibrator, means having a piezoelectric effect may be used or electrostatic drive with Coulomb force may be used.

The vibrator element 340 is a double T type vibrator element, and has drive arms 341 and 342, a detection arm 343, a base portion 344, and connection arms 345 and 346 which connect the base portion 344 and the drive arms 341 and 342. A plurality of electrodes (not shown) are provided on the lower surface side (on the negative direction side of the Z axis) of the base portion 344, and leads 351, 352, 353, 354, 355, and 356 are connected to these electrodes. The leads 351 and 352 and the electrodes connected to these leads are, for example, leads and electrodes for detection (for detection signal or for detection ground). The leads 353, 354, 355, and 356 and the electrodes connected to these leads are, for example, leads and electrodes for drive (for drive signal or for drive ground).

The vibrator element 360 is an H type vibrator element, and has drive arms 361 and 362, detection arms 363 and 364, and a base portion 365. A plurality of electrodes (not shown) are provided on the lower surface side (on the negative direction side of the Z axis) of the base portion 365, and leads 371, 372, 373, 374, 375, and 376 are connected to these electrodes. The leads 371 and 372 and the electrodes connected to these leads are, for example, leads and electrodes for drive (for drive signal or for drive ground). The leads 373, 374, 375, and 376 and the electrodes connected to these electrodes are leads and electrodes for detection (for detection signal or for detection ground). A pair of adjustment arms may be provided in addition to drive arms 361 and 362 and the detection arms 363 and 364.

As shown in FIGS. 5 and 6, the package 310 has an internal space S which is formed by closing the opening of the recess portion of the base 312 with the lid 314. In the internal space S, the angular velocity sensors 13 and 14 (vibrator elements 340 and 360) and the circuit device 20 (IC) are housed. The internal space S is sealed hermetically and is in a decompressed state (for example, vacuum).

In the base 312, a plurality of internal terminals 316 and a plurality of internal terminals 318 are provided so as to surround the internal space S. The internal terminals 318 are connected to external terminals 315 formed on the bottom surface of the base 312 through internal wirings (not shown) formed in the base 312. The internal terminals 318 are connected to the circuit device 20 through bonding wires 382, and are connected to the internal terminals 316 through the internal wirings (not shown). In FIG. 5, the internal terminal 316 is electrically connected to the angular velocity sensor 13 (vibrator element 340) through the lead 352 (351, 353 to 356), thereby electrically connecting the circuit device 20 and the angular velocity sensor 13. In FIG. 6, the internal terminal 316 is electrically connected to the angular velocity sensor 14 (vibrator element 360) through the lead 372 (371, 373 to 376), thereby electrically connecting the circuit device 20 and the angular velocity sensor 14.

A support substrate 330 is a TAB substrate for tape automated bonding (TAB) mounting. As shown in FIGS. 3 to 5, the support substrate 330 has a frame-shaped base portion 332, and a plurality of leads 351 to 356 and 371 to 376 provided in the base portion 332. The base portion 332 is fixed to the base 312. The vibrator element 340 of the angular velocity sensor 13 is fixed to the tip portions of the leads 351 to 356. The vibrator element 360 of the angular velocity sensor 14 is fixed to the tip portions of the leads 371 to 376. With this, the vibrator elements 340 and 360 are fixed to (supported by) the base 312 through the support substrate 330.

Specifically, each of the leads 351 to 356 and 371 to 376 is inclined halfway, and as shown in FIGS. 5 and 6, the tip portion of each lead is positioned above the base portion 332 through an opening 334 of the support substrate 330. With this, it is possible to fix the vibrator elements 340 and 360 to the tip portions of the leads 351 to 356 and 371 to 376 above the support substrate 330 without being obstructed by the base portion 332.

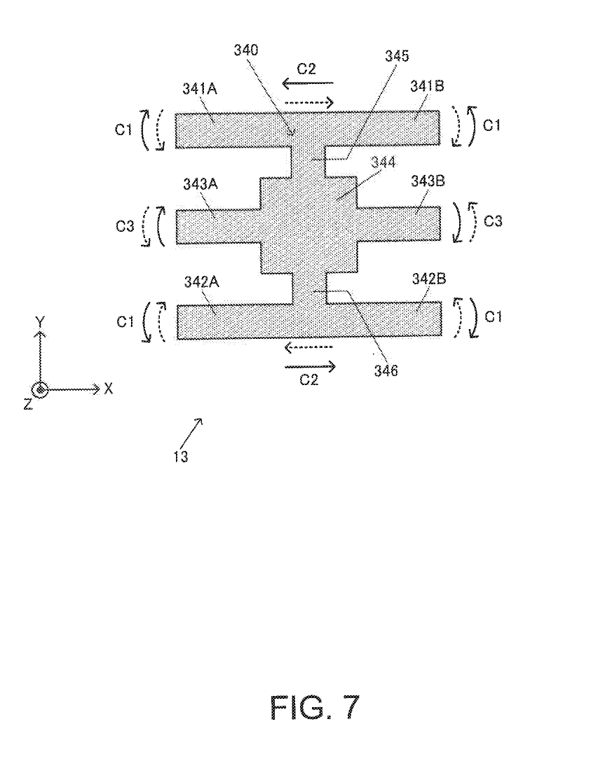

FIG. 7 is a diagram schematically illustrating the operation of the angular velocity sensor 13. The angular velocity sensor 13 is a double T type gyro sensor which detects the angular velocity around the Z axis.

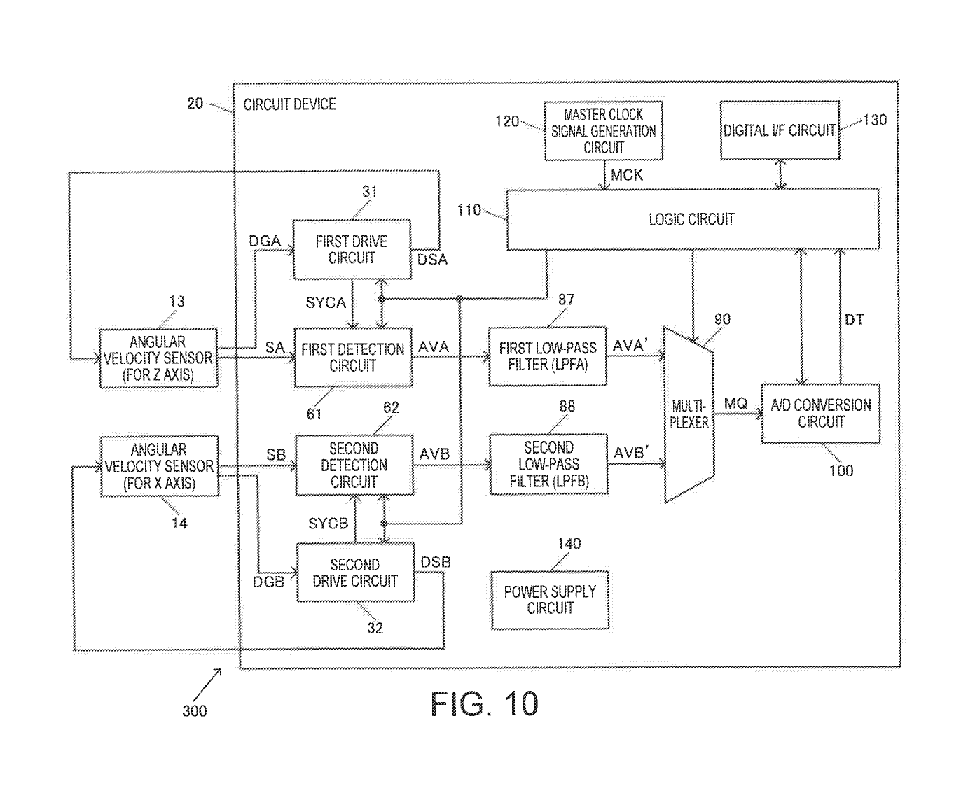

If an AC drive signal DSA is applied by a first drive circuit 31 of FIG. 10 described below, drive arms 341A, 341B, 342A, and 342B perform flexural vibration (excitation vibration) indicated by an arrow C1 with an inverse piezoelectric effect. For example, a vibration form indicated by an arrow of a solid line and a vibration form indicated by an arrow of a dotted line are repeated at a predetermined frequency. That is, flexural vibration is performed in which the tips of the drive arms 341A and 342A repeat approach and separation with respect to each other and the tips of the drive arms 341B and 342B repeat approach and separation with respect to each other. At this time, since the drive arms 341A and 341B and the drive arms 342A and 342B perform line-symmetrical vibration with respect to the X axis passing through the center position of the base portion 344, the base portion 344, the connection arms 345 and 346, and the detection arms 343A and 343B do not almost vibrate.

In this state, if an angular velocity with the Z axis as a rotation axis is applied to the vibrator element 340 (if the vibrator element 340 rotates around the Z axis), the drive arms 341A, 341B, 342A, and 342B vibrate as indicated by an arrow C2 with Coriolis force. That is, the Coriolis force in the direction of the arrow C2 orthogonal to a direction of an arrow C1 and the direction of the Z axis is applied to the drive arms 341A, 341B, 342A, and 342B, whereby a vibration component in the direction of the arrow C2 is generated. The vibration of the arrow C2 is transmitted to the base portion 344 through the connection arms 345 and 346, and accordingly, the detection arms 343A and 343B perform flexural vibration in a direction of an arrow C3. An electric charge signal generated with a piezoelectric effect according to the flexural vibrations of the detection arms 343A and 343B are input to the first detection circuit 61 of FIG. 10 as the detection signal SA (differential detection signal), and the angular velocity around the Z axis is detected. The detection signal SA is a signal which has a phase shifted by 90 degrees from the drive signal DSA of FIG. 10.

For example, if the angular velocity of the vibrator element 340 around the Z axis is w, a mass is m, and a vibration velocity is v, the Coriolis force is represented as Fc=2m·v·ω. Therefore, the first detection circuit 61 detects a desired signal which is a signal according to the Coriolis force, whereby it is possible to determine the angular velocity ω around the Z axis.

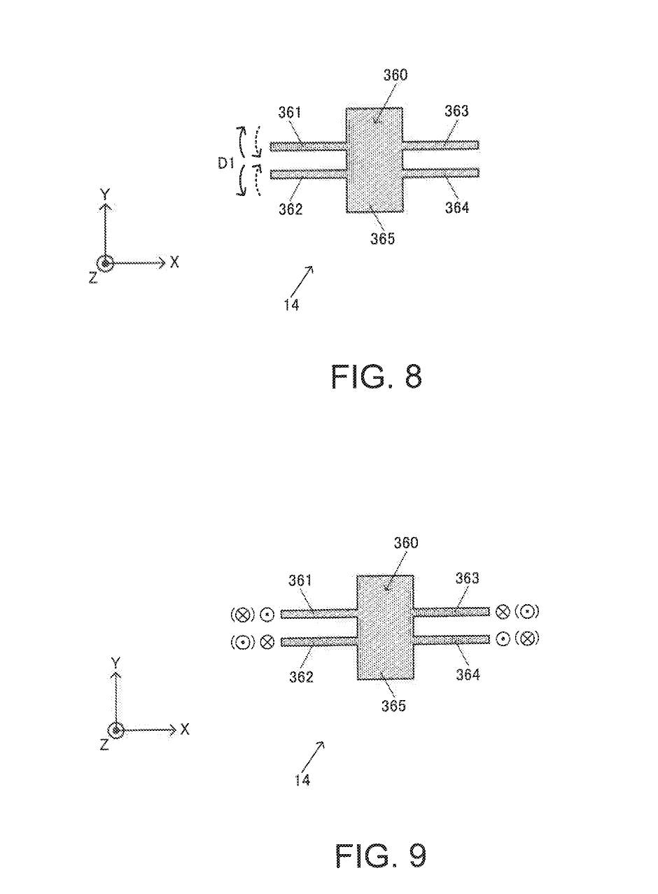

FIGS. 8 and 9 are diagrams schematically illustrating the operation of the angular velocity sensor 14. The angular velocity sensor 14 is an H type gyro sensor which detects the angular velocity around the X axis.

If an AC drive signal DSB is applied by a second drive circuit 32 of FIG. 10, as indicated by an arrow Dl of FIG. 8, the drive arms 361 and 362 perform flexural vibration in an opposite phase in the Y-axis direction. For example, a vibration form indicated by an arrow of a solid line and a vibration form indicated by an arrow of a dotted line are repeated at a predetermined frequency. In this state, since the vibrations of the drive arms 361 and 362 cancel each other, the detection arms 363 and 364 do not substantially vibrate. In this state, if an angular velocity with the X axis as a rotation axis is applied to the vibrator element 360 (if the vibrator element 360 rotates around the X axis), the Coriolis force is applied to the drive arms 361 and 362, and as shown in FIG. 9, the flexural vibrations in the Z-axis direction are excited. Then, the detection arms 363 and 364 perform flexural vibration in the Z-axis direction so as to respond to the flexural vibrations of the drive arms 361 and 362. An electric charge signal generated with a piezoelectric effect according to the flexural vibration is input to the second detection circuit 62 of FIG. 10 as the detection signal SB (differential signal), and the angular velocity around the X axis is detected.

As described above, in the physical quantity detection device 300 of this embodiment, the angular velocity sensors 13 and 14 shown in FIG. 4 are provided as the first and second physical quantity transducers 11 and 12 of FIG. 1. As shown in FIGS. 5 and 6, the angular velocity sensors 13 and 14 are arranged above the circuit device 20 (on the positive direction side of the Z axis). Specifically, the angular velocity sensor 13 is arranged above the first detection circuit 61 of FIGS. 2 and 3, and the angular velocity sensor 14 is arranged above the second detection circuit 62. For example, the third direction DR3 of FIGS. 2 and 3 corresponds to the Y-axis direction of FIG. 4, and the third direction DR4 corresponds to the X-axis direction.

In this way, according to the arrangement configuration examples of FIGS. 2 and 3, the angular velocity sensor 13 is arranged above (at a position near above) the first detection circuit 61, and the angular velocity sensor 14 is arranged above (at a position near above) the second detection circuit 62. Therefore, it is possible to make the first signal path between the first detection circuit 61 and the angular velocity sensor 13 or the second signal path between the second detection circuit 62 and the angular velocity sensor 14 into a shorter signal path.

For example, in FIG. 5, it is possible to make the first signal path from the circuit device 20 to the angular velocity sensor 13 through the bonding wire 382, the internal terminal 318, the internal wiring (not shown), the internal terminal 316, and the lead 352 into a shorter signal path. In FIG. 6, it is possible to make the second signal path from the circuit device 20 to the angular velocity sensor 14 through the bonding wires 382, the internal terminal 318, the internal wiring (not shown), the internal terminal 316, and the lead 372 into a shorter signal path. Therefore, in a case where signals (SA, SB, and the like) having weak amplitude are transmitted through the first and second signal paths, it is possible to reduce noise superimposed on these signals, and to effectively reduce deterioration of detection characteristics or the like.

The bonding wire 382 of FIG. 5 is connected to the pads TA1 and TA2 (two pads for input of a detection signal as a differential signal) for the first detection circuit 61 of FIGS. 2 and 3. The bonding wire 382 of FIG. 6 is connected to the pads TB1 and TB2 (two pads for input of a detection signal as a differential signal) for the second detection circuit 62.

### 3. Detailed Configuration Example

FIG. 10 shows a detailed configuration example of the circuit device 20 and the physical quantity detection device 300 of this embodiment. In FIG. 10, the angular velocity sensors 13 and 14 are provided as the first and second physical quantity transducers 11 and 12 of FIG. 1. As described referring to FIGS. 4 to 9, the angular velocity sensor 13 is a sensor which detects the angular velocity around the Z axis, and the angular velocity sensor 14 is a sensor which detects the angular velocity around the X axis. The circuit device 20 is provided with, in addition to the first and second detection circuits 61 and 62, the multiplexer 90, the A/D conversion circuit 100, and the logic circuit 110 described referring to FIG. 1, first and second drive circuits 31 and 32, first and second low-pass filters 87 and 88, a master clock signal generation circuit 120, a digital interface circuit (digital I/F circuit) 130, and a power supply circuit 140. It should be noted that the circuit device 20 and the physical quantity detection device 300 are not limited to the configurations of FIG. 10, and may be modified in various ways such that a part of the constituent elements may be omitted or other constituent elements may be added.

The first drive circuit 31 is a circuit which drives the angular velocity sensor 13 (in a broad sense, the first physical quantity transducer). For example, the first drive circuit 31 outputs the drive signal DSA to drive the angular velocity sensor 13. Specifically, the first drive circuit 31 performs drive to vibrate the vibrator element 340 (FIG. 4) of the angular velocity sensor 13 at a drive frequency. For example, the first drive circuit 31 receives a feedback signal DGA from the angular velocity sensor 13 and outputs the square or sine-wave drive signal DSA to the angular velocity sensor 13. With this, the angular velocity sensor 13 is driven at a constant drive frequency, and for example, the vibrator element 340 vibrates at a frequency according to the drive frequency. The first drive circuit 31 outputs a synchronization signal SYCA for synchronization detection to the first detection circuit 61.

The second drive circuit 32 is a circuit which drives the angular velocity sensor 14 (in a broad sense, the second physical quantity transducer). For example, the second drive circuit 32 outputs the drive signal DSB to drive the angular velocity sensor 14. Specifically, the second drive circuit 32 performs drive to vibrate the vibrator element 360 (FIG. 4) of the angular velocity sensor 14 at the drive frequency. For example, the second drive circuit 32 receives a feedback signal DGB from the angular velocity sensor 14 and outputs the square or sine-wave drive signal DSB to the angular velocity sensor 14. With this, the angular velocity sensor 14 is driven at a constant drive frequency, and for example, the vibrator element 360 vibrates at a frequency according to the drive frequency. The second drive circuit 32 outputs a synchronization signal SYCB for synchronization detection to the second detection circuit 62.

The first detection circuit 61 receives the detection signal SA (differential signal) from the angular velocity sensor 13 driven by the first drive circuit 31 and detects an angular velocity signal AVA (in a broad sense, the first physical quantity signal). Specifically, the first detection circuit 61 performs synchronization detection using the synchronization signal SYCA from the first drive circuit 31 and detects and outputs the angular velocity signal AVA as a desired signal. The angular velocity signal AVA is, for example, a signal representing the angular velocity (in a broad sense, the first physical quantity) around the Z axis.

The second detection circuit 62 receives the detection signal SB (differential signal) from the angular velocity sensor 14 driven by the second drive circuit 32 and detects an angular velocity signal AVB (in a broad sense, the second physical quantity signal). Specifically, the second detection circuit 62 performs synchronization detection using the synchronization signal SYCB from the second drive circuit 32 and detects and outputs the angular velocity signal AVB as a desired signal. The angular velocity signal AVB is, for example, a signal representing the angular velocity (in a broad sense, the second physical quantity) around the X axis.

The first low-pass filter 87 (LPFA) performs low-pass filter processing of the angular velocity signal AVA (first physical quantity signal) from the first detection circuit 61. For example, the first low-pass filter 87 is provided between the first detection circuit 61 and the multiplexer 90. The first low-pass filter 87 is a passive filter which is constituted of, for example, a passive element, such as a resistor or a capacitor, and performs analog low-pass filter processing to output angular velocity signal AVA′ after the low-pass filter processing to the multiplexer 90.

The second low-pass filter 88 (LPFB) performs low-pass filter processing of the angular velocity signal AVB (second physical quantity signal) from the second detection circuit 62. For example, the second low-pass filter 88 is provided between the second detection circuit 62 and the multiplexer 90. The second low-pass filter 88 is a passive filter which is constituted of, for example, a passive element, such as a resistor or a capacitor, and performs analog low-pass filter processing to output an angular velocity signal AVB′ after the low-pass filter processing to the multiplexer 90.

The first and second low-pass filters 87 and 88 function as pre-filters (anti-aliasing filters) of the A/D conversion circuit 100. A frequency component of a detuning frequency is removed by the first and second low-pass filters 87 and 88. The detuning frequency is a frequency corresponding to the difference between a resonance frequency (drive frequency) of a drive vibration mode and a resonance frequency (detection frequency) of a detection vibration mode. The detuning frequency is a frequency in a range of, for example, several hundreds of Hz to several KHz. Since the frequency component of the detuning frequency is not removed by synchronization detection, it is necessary to attenuate the frequency component of the detuning frequency through the low-pass filter processing of the first and second low-pass filters 87 and 88.

The multiplexer 90 selects any one signal among a plurality of signals including the angular velocity signals AVA′ and AVB′ input from the first and second detection circuits 61 and 62 through the first and second low-pass filters 87 and 88. The multiplexer 90 outputs the selected signal to the A/D conversion circuit 100 as the signal MQ. Specifically, the multiplexer 90 performs selection processing of a signal for time-division A/D conversion in the A/D conversion circuit 100. For example, in a first period, the multiplexer 90 selects the angular velocity signal AVA′ from the first detection circuit 61 (first low-pass filter 87) and outputs the angular velocity signal AVA′ to the A/D conversion circuit 100 as the signal MQ, and the A/D conversion circuit 100 performs A/D conversion of the angular velocity signal AVA′ as the signal MQ. In a second period next to the first period, the multiplexer 90 selects the angular velocity signal AVB′ from the second detection circuit 62 (second low-pass filter 88) and outputs the angular velocity signal AVB′ to the A/D conversion circuit 100 as the signal MQ, and the A/D conversion circuit 100 performs A/D conversion of the angular velocity signal AVB′ as the signal MQ. The signal selection in the multiplexer 90 is performed based on a control signal from the logic circuit 110. In addition to the angular velocity signals AVA′ andAVB′, an analog signal (for example, a temperature detection signal or the like) may be input to the multiplexer 90, and in this case, the A/D conversion circuit 100 performs A/D conversion of the angular velocity signals AVA′ and AVB′ and the analog signal in a time-division manner.

The master clock signal generation circuit 120 generates a master clock signal MCK of the circuit device 20. The logic circuit 110 operates based on the master clock signal MCK. The master clock signal MCK is a clock signal which becomes a reference of a circuit block, such as the logic circuit 110. For example, the logic circuit 110 divides the master clock signal MCK and supplies various clock signals after division to the respective circuit blocks, such as the first and second drive circuits 31 and 32, the first and second detection circuits 61 and 62, and the A/D conversion circuit 100, to operate these circuit blocks.

The digital I/F circuit 130 is a circuit which performs at least one of an input or an output of a digital signal. For example, the digital I/F circuit 130 can be implemented with a circuit which performs serial interface processing. For example, the digital I/F circuit 130 can be implemented with a two-line, three-line, or four-line serial interface circuit including a serial data line and a serial clock line. That is, the interface processing of the digital I/F circuit 130 can be implemented with a synchronous serial communication system using a serial clock line and a serial data line. For example, the interface circuit can be implemented with a three-line or four-line serial peripheral interface (SPI) system, an inter-integrated circuit (I2C) system, or the like.

The power supply circuit 140 generates various power supply voltages and supplies various power supply voltages to the respective circuit blocks of the circuit device 20. For example, the power supply circuit 140 performs a regulation operation of a power supply voltage input through an external connection terminal (pad) of the circuit device 20 to generate power supply voltages of various voltages. Then, the power supply circuit 140 supplies the power supply voltages of various voltages to the respective circuit blocks, such as the first and second drive circuits 31 and 32, the first and second detection circuits 61 and 62, the A/D conversion circuit 100, the logic circuit 110, the master clock signal generation circuit 120, and the digital I/F circuit 130. The power supply circuit 140 can be implemented with a regulator circuit which performs a regulation operation of a voltage, a circuit which generates a reference current or a reference voltage, or the like.

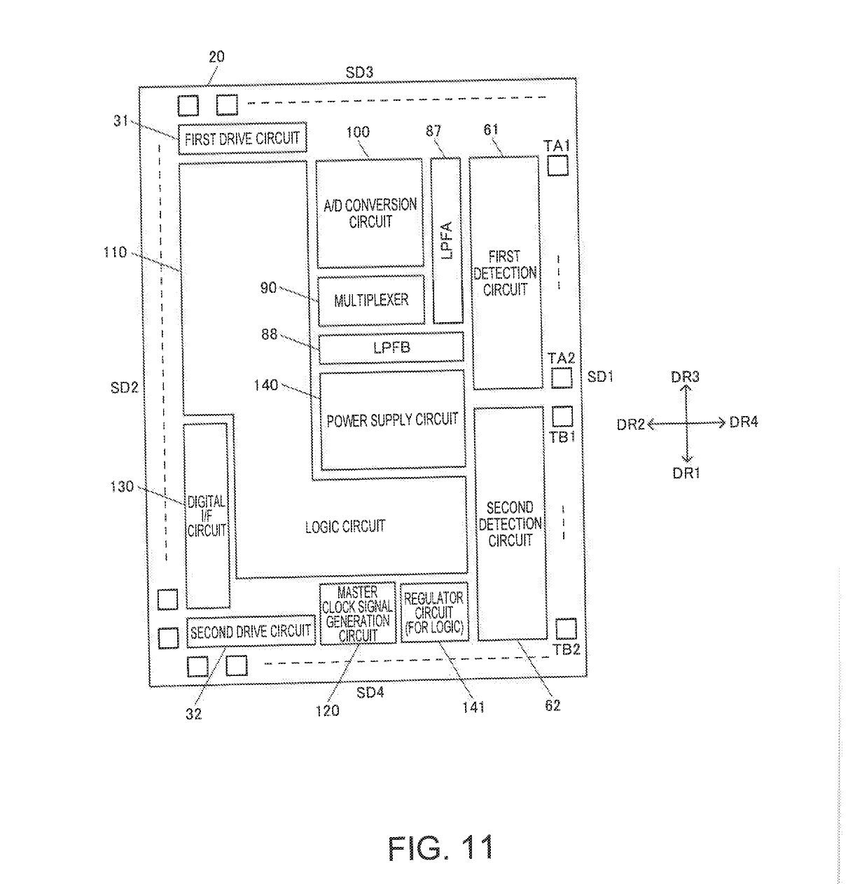

FIG. 11 shows an arrangement configuration example of the circuit blocks of the circuit device 20 of FIG. 10. FIG. 11 is a diagram showing a layout arrangement example of the semiconductor chip of the circuit device 20. In FIG. 11, as in FIGS. 2 and 3, the first detection circuit 61 is arranged on the second direction DR2 side from the first side SD1, and the second detection circuit 62 is arranged on the second direction DR2 side from the first side SD1 and the first direction DR1 side from the first detection circuit 61. The first and second detection circuits 61 and 62 are arranged in this way, whereby the first detection circuit 61 is arranged below the angular velocity sensor 13 of FIG. 4 and the second detection circuit 62 is arranged below the angular velocity sensor 14.

The A/D conversion circuit 100 is arranged between at least one of the first or second detection circuit, 61 or 62, and the logic circuit 110. In FIG. 11, the A/D conversion circuit 100 is arranged between the first detection circuit 61 and the logic circuit 110. The multiplexer 90 is arranged between at least one of the first or second detection circuit, 61 or 62, and the logic circuit 110. In FIG. 11, the multiplexer 90 is arranged between the first detection circuit 61 and the logic circuit 110.

In FIG. 11, the A/D conversion circuit 100 is arranged on the third direction DR3 side from the multiplexer 90. The A/D conversion circuit 100 may be arranged on the first direction DR1 side from the multiplexer 90.

The circuit device 20 includes the power supply circuit 140 which supplies the power supply voltage. The power supply circuit 140 supplies the power supply voltage to the respective circuit blocks of the circuit device 20. In FIG. 11, the A/D conversion circuit 100 is arranged on the third direction DR3 side of the multiplexer 90, and in this case, the power supply circuit 140 is disposed on the first direction DR1 side from the multiplexer 90. That is, the multiplexer 90 is arranged between the A/D conversion circuit 100 and the power supply circuit 140. In a case where the A/D conversion circuit 100 is arranged on the first direction DR1 side of the multiplexer 90, the power supply circuit 140 may be arranged on the third direction DR3 side of the multiplexer 90.

If the power supply circuit 140 is arranged as in FIG. 11, it is possible to arrange the power supply circuit 140 near the center portion of the circuit device 20. The power supply circuit 140 distributes and supplies the power supply voltage to the respective circuit blocks (the first and second detection circuits 61 and 62, the first and second drive circuits 31 and 32, the A/D conversion circuit 100, and the like) of the circuit device 20. Therefore, the power supply circuit 140 is arranged near the center of the circuit device 20, whereby it is possible to optimize the length of a power line between the power supply circuit 140 and each circuit block. That is, in a case where the power supply voltage is supplied from the power supply circuit 140 to a plurality of circuit blocks, it is possible to prevent a situation in which only the length of power lines to a part of the circuit blocks becomes extremely long. Therefore, wiring efficiency of the power lines is improved, and optimization of impedance of power supply is achieved.

In FIG. 11, as in FIGS. 2 and 3, the logic circuit 110 is arranged on the fourth direction DR4 side from the second side SD2 and on the second direction DR2 side of at least one (in FIG. 11, both) of the first or second detection circuit, 61 or 62.

The circuit device 20 includes a first low-pass filter 87 (LPFA) which performs low-pass filter processing of an angular acceleration signal AVA (first physical quantity signal). The first low-pass filter 87 is arranged between the first detection circuit 61 and the multiplexer 90 (A/D conversion circuit 100). For example, the first low-pass filter 87 is positioned on a signal path between the first detection circuit 61 and the multiplexer 90. For example, the first low-pass filter 87 is arranged adjacent to the multiplexer 90. For example, in FIG. 11, the first low-pass filter 87 is arranged on the second direction DR2 side from the first detection circuit 61, and the multiplexer 90 is arranged on the second direction DR2 side from the first low-pass filter 87. With this, it is possible to transmit a signal, which is input from the first detection circuit 61 to the first low-pass filter 87, from the first low-pass filter 87 to the multiplexer 90 in a short path.

The circuit device 20 includes a second low-pass filter 88 (LPFB) which performs low-pass filter processing of an angular acceleration signal AVB (second physical quantity signal). The second low-pass filter 88 is arranged between the second detection circuit 62 and the multiplexer 90 (A/D conversion circuit 100). For example, the second low-pass filter 88 is positioned on a signal path between the second detection circuit 62 and the multiplexer 90. For example, the second low-pass filter 88 is arranged adjacently to the multiplexer 90. With this, it is possible to transmit a signal, which is input from the second detection circuit 62 to the second low-pass filter 88, from the second low-pass filter 88 to the multiplexer 90 in a short path.

For example, in a case where the first and second low-pass filters 87 and 88 are passive filters, the output impedance thereof is high. In particular, in a case where the first and second low-pass filters 87 and 88 have low-pass filter characteristics for removing a detuning frequency component, the output impedance thereof becomes excessively high. Accordingly, if the signal wiring between the first low-pass filter 87 and the multiplexer 90 (A/D conversion circuit 100) is extended or if the signal wiring between the second low-pass filter 88 and the multiplexer 90 (A/D conversion circuit 100) is extended, the characteristics (S/N and the like) of a signal to be transmitted are deteriorated.

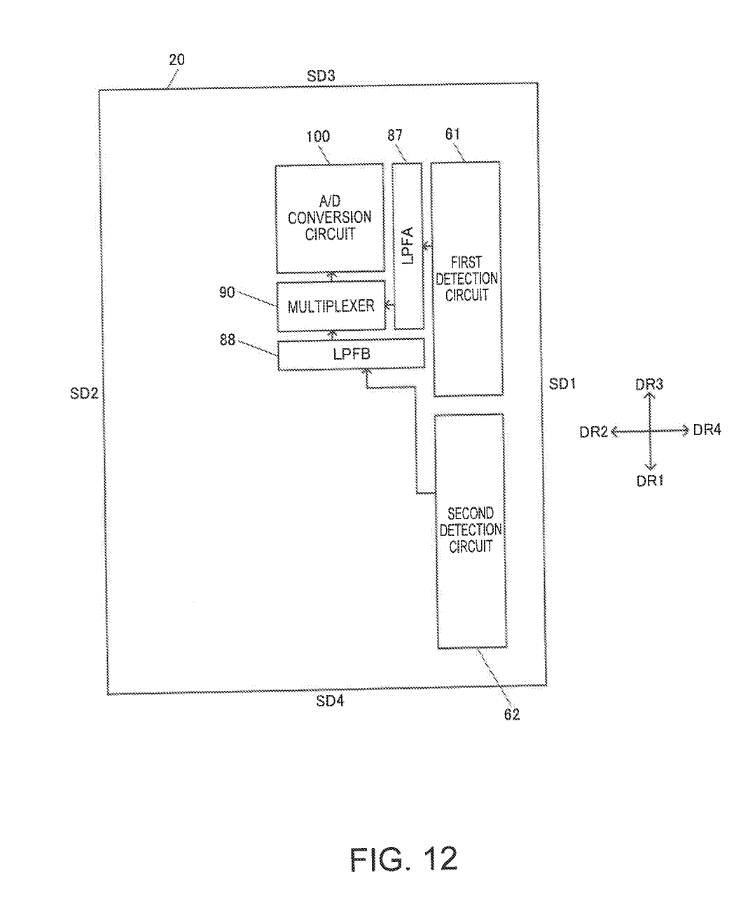

From this, in this embodiment, as shown in FIG. 12, the first low-pass filter 87 is arranged between the first detection circuit 61 and the multiplexer 90, and the multiplexer 90 is arranged adjacently to the first low-pass filter 87. With this, it is possible to shorten the signal wiring between the first low-pass filter 87 and the multiplexer 90. Therefore, even in a case where the first low-pass filter 87 is a passive filter and the output impedance thereof is high, it is possible to shorten the signal wiring, thereby reducing signal deterioration.

In this embodiment, as shown in FIG. 12, the second low-pass filter 88 is arranged between the second detection circuit 62 and the multiplexer 90, and the multiplexer 90 is arranged adjacent to the second low-pass filter 88. With this, it is possible to shorten the signal wiring between the second low-pass filter 88 and the multiplexer 90. Therefore, even in a case where the second low-pass filter 88 is a passive filter and the output impedance thereof is high, it is possible to shorten the signal wiring, thereby reducing signal deterioration. That is, since the second detection circuit 62 outputs a signal, for example, using a buffer circuit, the output impedance of the second detection circuit 62 is comparatively low. Accordingly, even if the signal wiring between the second detection circuit 62 and the second low-pass filter 88 is extended, there is no adverse effect so much. In contrast, since the output impedance of the second low-pass filter 88 is excessively high, if the signal wiring between the second low-pass filter 88 and the multiplexer 90 is extended, a problem of signal deterioration occurs. From this, in this embodiment, since the signal wiring between the second low-pass filter 88 and the multiplexer 90 becomes shorter than the signal wiring between the second low-pass filter 88 and the second detection circuit 62, it is possible to solve the above-described problem of signal deterioration.

The A/D conversion circuit 100 is arranged adjacent to the multiplexer 90. In FIG. 12, the A/D conversion circuit 100 is arranged adjacent to the multiplexer 90 on the third direction DR3 side from the multiplexer 90. With this, it is possible to input the output signal of the multiplexer 90 to the A/D conversion circuit 100 in a short path. Therefore, it is possible to reduce deterioration of signal characteristics due to superimposition of noise or the like on the output signal from the multiplexer 90 having high output impedance. For example, the A/D conversion circuit 100 has an amplification circuit, such as a programmable gain amplifier, in the pre-stage thereof as described below. While signal deterioration of an input signal of the amplification circuit (the output signal of the multiplexer 90) is significant, since the amplification circuit has low output impedance, even if a signal wiring for an output signal of the amplification circuit is long, signal deterioration is less significant.

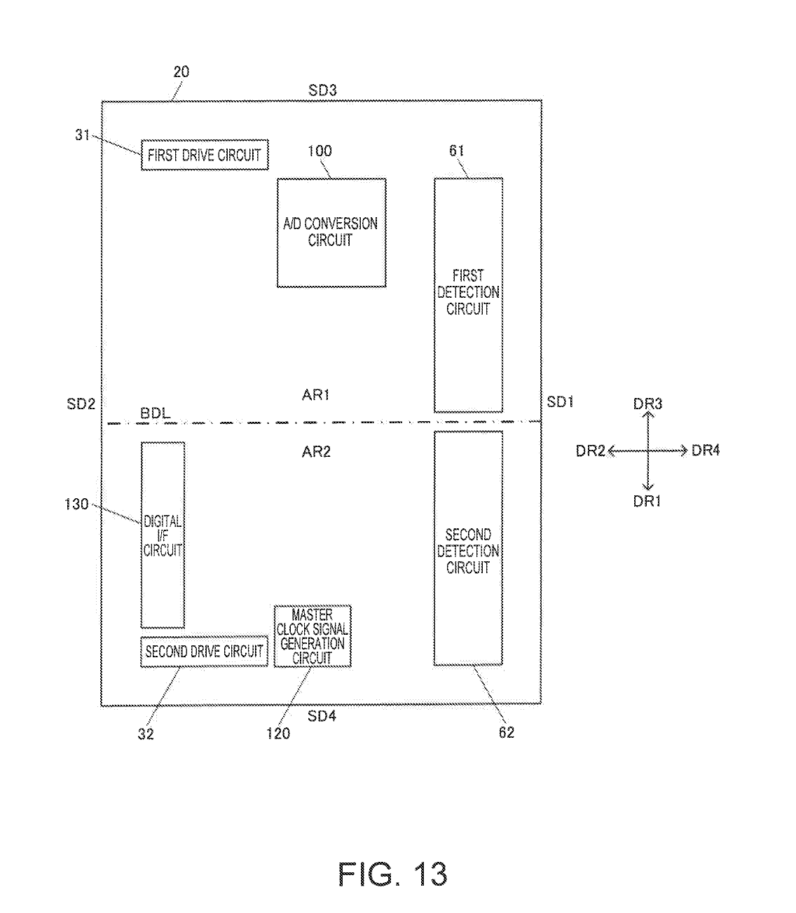

In FIG. 13, the third side SD3 of the circuit device 20 is a side which intersects the first and second sides SD1 and SD2. The fourth side SD4 is a side which intersects the first and second sides SD1 and SD2 and is opposite to the third side SD3. A line parallel to the third side SD3 and the fourth side SD4 is referred to as a boundary line BDL. The boundary line BDL is a line (virtual line) which is set between the third side SD3 and the fourth side SD4 and is a line which extends along the second direction DR2 near the center of the circuit device 20. An area of the circuit device 20 divided by the boundary line BDL and the third side SD3 is referred to as a first area AR1, and an area of the circuit device 20 divided by the boundary line BDL and the fourth side SD4 is referred to as a second area AR2.

In this case, in this embodiment, as shown in FIG. 13, the first detection circuit 61 is arranged in the first area AR1, and the second detection circuit 62 is arranged in the second area AR2. That is, the first detection circuit 61 is arranged in an area on the third direction DR3 side from the boundary line BDL near the center of the circuit device 20, and the second detection circuit 62 is arranged in an area on the first direction DR1 side from the boundary line BDL.

With this, in a case where the angular velocity sensor 13 is arranged above the first area AR1 of the circuit device 20 and the angular velocity sensor 14 is arranged above the second area AR2 as in FIG. 4, it is possible to shorten the signal paths between the first and second detection circuits 61 and 62 and the angular velocity sensors 13 and 14. These signal paths are shortened, whereby, in a case where the first and second detection circuits 61 and 62 detect weak signals from the angular velocity sensors 13 and 14, it is possible to effectively reduce deterioration of detection characteristics due to noise superimposed on the weak signals.

The circuit device 20 includes a first drive circuit 31 which drives the angular velocity sensor 13 (first physical quantity transducer). As shown in FIG. 13, the first drive circuit 31 is also arranged in the first area AR1. That is, both of the first detection circuit 61 which detects a signal from the angular velocity sensor 13 and the first drive circuit 31 which drives the angular velocity sensor 13 are arranged in the first area AR1.

With this, in a case where the angular velocity sensor 13 is arranged above the first area AR1 of the circuit device 20 as in FIG. 4, it is possible to shorten the signal path between the first drive circuit 31 and the angular velocity sensor 13. The signal path is shortened in this way, whereby it is possible to output a drive signal from the first drive circuit 31 to the angular velocity sensor 13 in a short path, and to enable efficient drive of the angular velocity sensor 13.

A second drive circuit 32 which drives the angular velocity sensor 14 (second physical quantity transducer) is arranged in the second area AR2 as shown in FIG. 13. That is, both of the second detection circuit 62 which detects a signal from the angular velocity sensor 14 and the second drive circuit 32 which drives the angular velocity sensor 14 are arranged in the second area AR2. With this, in a case where the angular velocity sensor 14 is arranged above the second area AR2 of the circuit device 20 as in FIG. 4, it is possible to shorten the signal path between the second drive circuit 32 and the angular velocity sensor 14. With this, it is possible to output a drive signal from the second drive circuit 32 to the angular velocity sensor 14 in a short path, and to enable efficient drive of the angular velocity sensor 14. In a case where the second physical quantity transducer 12 is an acceleration sensor or the like, the arrangement of the second drive circuit 32 in the second area AR2 shown in FIG. 13 is not required.

In this embodiment, the first drive circuit 31 is arranged between the third side SD3 of the circuit device 20 and the logic circuit 110 or between the second side SD2 and the logic circuit 110. For example, in FIG. 11, the first drive circuit 31 is arranged between the third side SD3 of the circuit device 20 and the logic circuit 110. For example, the first drive circuit 31 is arranged on the first direction DR1 side of an I/O area (pad arrangement area) arranged along the third side SD3. The logic circuit 110 is arranged on the first direction DR1 side of the first drive circuit 31. In this case, the I/O area and the first drive circuit 31 are arranged, for example, adjacently each other in the first direction DR1. The first drive circuit 31 and the logic circuit 110 are also arranged adjacently each other in the first direction DR1. Even in a case where the first drive circuit 31 is arranged between the second side SD2 and the logic circuit 110, the same layout arrangement is made. For example, the first drive circuit 31 is arranged, for example, adjacently to the fourth direction DR4 side of an I/O area along the first side SD2. The logic circuit 110 is arranged, for example, adjacently to the fourth direction DR4 side of the first drive circuit 31.

If the first drive circuit 31 is arranged in this way, for example, it is possible to separate the distance between the first drive circuit 31 and the first detection circuit 61. For example, the first drive circuit 31 is arranged in a corner portion where the second side SD2 and the third side SD3 intersect each other, and therefore it is possible to extend the distance between the first drive circuit 31 and the first detection circuit 61. With this, it is possible to reduce an adverse effect of noise generated in the first drive circuit 31 on the detection characteristics of the first detection circuit 61. For example, in a case where the first drive circuit 31 drives the angular velocity sensor 13 with a square-wave drive signal or the like, large noise is generated in the first drive circuit 31. Since this noise is noise of a drive frequency, if the noise is transmitted to the first detection circuit 61, the detection characteristics are significantly deteriorated. For example, if noise of the drive frequency which is a frequency close to a detection frequency is transmitted to the first detection circuit 61, since it is difficult to remove the noise, the detection characteristics are significantly deteriorated. From this, in FIG. 11, since it is possible to maximize separation of the first drive circuit 31 from the first detection circuit 61, it is possible to effectively reduce deterioration of the detection characteristics due to the noise.

In this embodiment, it is desirable that the second drive circuit 32 is also arranged between the fourth side SD4 of the circuit device 20 and the logic circuit 110 or between the second side SD2 and the logic circuit 110. For example, in FIG. 11, the second drive circuit 32 is arranged between the fourth side SD4 of the circuit device 20 and the logic circuit 110. For example, the second drive circuit 32 is arranged, for example, adjacently to the third direction DR3 side of the I/O area along the fourth side SD4. Specifically, the second drive circuit 32 is arranged in a corner portion where the second side SD2 and the fourth side SD4 intersect each other. If the arrangement is made in this way, for example, it is possible to separate the distance between the second drive circuit 32 and the second detection circuit 62, and to reduce an adverse effect of noise generated in the second drive circuit 32 on the detection characteristics of the second detection circuit 62.

As shown in FIG. 13, the A/D conversion circuit 100 is arranged in the first area AR1. That is, the A/D conversion circuit 100 is arranged in the first area AR1 along with the first detection circuit 61. With this, it is possible to approach the distance between the first detection circuit 61 and the A/D conversion circuit 100, and to input a signal from the first detection circuit 61 to the A/D conversion circuit 100 in a short path. Therefore, it is possible to execute A/D conversion of an analog signal while minimizing noise superimpose on the analog signal.

The circuit device 20 includes a master clock signal generation circuit 120 which generates a master clock signal. As shown in FIG. 13, the master clock signal generation circuit 120 is arranged in the second area AR2. With this, it is possible to extend the distance between the master clock signal generation circuit 120 and the A/D conversion circuit 100. It is also possible to extend the distance between the master clock signal generation circuit 120 and the first detection circuit 61. For example, since the frequency of the master clock signal is high (for example, several MHz to several tens of MHz), the master clock signal generation circuit 120 becomes a large noise source. For example, the master clock signal generation circuit 120 has an oscillation circuit as described below, and large noise is generated from the oscillation circuit. If the master clock signal generation circuit 120 is arranged in the second area AR2 and the A/D conversion circuit 100 is arranged in the first area AR1, it is possible to separate the distance between the master clock signal generation circuit 120 and the A/D conversion circuit 100, and to effectively reduce an adverse effect of noise from the master clock signal generation circuit 120 on analog characteristics of the A/D conversion circuit 100.

As described below, in a case where the first detection circuit 61 is a detection circuit for an angular velocity sensor and the second detection circuit 62 is a detection circuit for an acceleration sensor, since the first detection circuit 61 handles a weaker signal than in the second detection circuit 62, the degree of adverse effect of noise on the detection characteristics is large. From this, if the master clock signal generation circuit 120 is arranged in the second area AR2 and the first detection circuit 61 is arranged in the first area AR1, it is possible to separate the distance between the master clock signal generation circuit 120 and the first detection circuit 61. Therefore, it is possible to effectively reduce an adverse effect of noise due to the generation of the master clock signal on the detection characteristics of the first detection circuit 61.

The circuit device 20 of this embodiment includes a digital I/F circuit 130 which performs at least one of an input or an output of a digital signal. As shown in FIG. 11, the digital I/F circuit 130 is arranged between the logic circuit 110 and the second side SD2. For example, the digital I/F circuit 130 is arranged on the fourth direction DR4 side of an I/O area (pad arrangement area) arranged along the second side SD2, and the logic circuit 110 is arranged on the fourth direction DR4 side of the digital I/F circuit 130. Specifically, the digital I/F circuit 130 is arranged adjacently to the fourth direction DR4 side of the I/O area, and the logic circuit 110 is arranged adjacently to the fourth direction DR4 side of the digital I/F circuit 130.

Apart of the circuits constituting the digital I/F circuit 130 may be arranged in the I/O area along the second side SD2. For example, an I/O buffer circuit or the like of the digital I/F circuit 130 may be arranged between the pads of the I/O area. Even in this case, the circuits constituting the digital I/F circuit 130 are arranged between the logic circuit 110 and the second side SD2.

In the digital I/F circuit 130, for example, since a signal in a clock signal line or a data line changes with voltage amplitude of, for example, about 3 V to 5 V, large digital noise is generated. A noise generation timing or the like depends on a processing timing of an external device, or the like, and is asynchronous with an internal timing of the circuit device 20. For this reason, if digital noise from the digital I/F circuit 130 is transmitted to the first and second detection circuits 61 and 62 or the A/D conversion circuit 100, there is a significant adverse effect on characteristics, such as the detection characteristics or A/D conversion characteristics.

From this, in FIGS. 11 and 13, the digital I/F circuit 130 is arranged along the second side SD2, and it is possible to sufficiently separate the distance between the digital I/F circuit 130 and the first and second detection circuits 61 and 62 or the A/D conversion circuit 100. Therefore, it is possible to reduce deterioration of the characteristics of the first and second detection circuits 61 and 62 or the A/D conversion circuit 100 due to digital noise from the digital I/F circuit 130. In particular, while large digital noise is generated in the pads (terminals) of a clock signal or a data signal of the digital I/F circuit 130, the distance between these pads and the first and second detection circuits 61 and 62 or the A/D conversion circuit 100 is separated, whereby it is possible to minimize characteristic deterioration.

In FIG. 11, a regulator circuit 141 for a logic is arranged on the third direction DR3 side from the fourth side SD4. For example, the regulator circuit 141 is arranged adjacently to the third direction DR3 side of the I/O area (pad arrangement area) along the fourth side. The regulator circuit 141 is a part of the circuits constituting the power supply circuit 140. For example, a digital power supply voltage generated by the regulator circuit 141 is stabilized by an external capacitor (bypass capacitor) as an external component. For this reason, in the I/O area on the first direction DR1 side of the regulator circuit 141, a connection pad (terminal) for connecting the external capacitor is arranged. Accordingly, the regulator circuit 141 is arranged on the third direction DR3 side from the fourth side SD4, whereby it is possible to shorten a wiring between the regulator circuit 141 and the connection pad, and to decrease the impedance of the wiring. With this, it is possible to implement stabilization of the digital power supply voltage with the external capacitor. Since large noise of a digital circuit is superimposed on the power supply voltage generated by the regulator circuit 141, the regulator circuit 141 becomes a large noise source. Accordingly, the regulator circuit 141 is arranged as in FIG. 11, whereby it is possible to separate the distance between the regulator circuit 141 to be a noise source and the first detection circuit 61 or the A/D conversion circuit 100, and to effectively reduce characteristic deterioration due to noise.

### 4. Detailed Configuration Example of Each Circuit Block

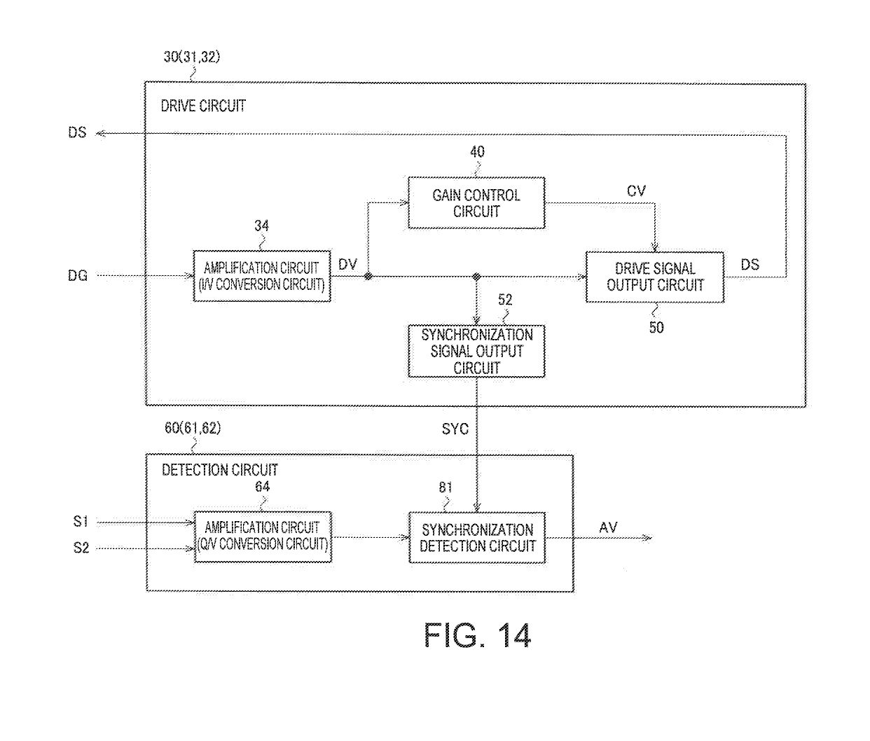

Next, a detailed configuration example of each circuit block of the circuit device 20 will be described. FIG. 14 shows a configuration example of a drive circuit 30 and a detection circuit 60. In FIG. 14, for simplification of description, the configuration of the first and second drive circuits 31 and 32 is shown as the configuration of the drive circuit 30, and the configuration of the first and second detection circuits 61 and 62 is shown as the configuration of the detection circuit 60.

The drive circuit 30 (31, 32) includes an amplification circuit 34 to which a feedback signal DG (DGA, DGB) from the angular velocity sensor (13, 14) is input, a gain control circuit 40 which performs automatic gain control, and a drive signal output circuit 50 which outputs a drive signal DS (DSA, DSB) to the angular velocity sensor (13, 14). Furthermore, the drive circuit 30 (31, 32) includes a synchronization signal output circuit 52 which outputs a synchronization signal SYC (SYCA, SYCB) to the detection circuit 60.

The amplification circuit 34 (I/V conversion circuit) amplifies the feedback signal DG from the angular velocity sensor (vibrator element). For example, the amplification circuit 34 converts a current signal DG from the angular velocity sensor to a voltage signal DV and outputs the voltage signal DV. The amplification circuit 34 can be implemented with an operational amplifier, a feedback resistor, a feedback capacitor, and the like.

The drive signal output circuit 50 outputs the drive signal DS based on the signal DV after amplification by the amplification circuit 34. For example, in a case where the drive signal output circuit 50 outputs a square-wave (or sine-wave) drive signal, the drive signal output circuit 50 can be implemented with a comparator or the like.

The gain control circuit 40 (AGC) outputs a control voltage CV to the drive signal output circuit 50 to control the amplitude of the drive signal DS. Specifically, the gain control circuit 40 monitors the signal DV to control a gain of an oscillation loop. For example, in the drive circuit 30, in order to maintain sensitivity of a gyro sensor uniform, it is necessary to maintain amplitude of a drive voltage supplied to the angular velocity sensor (vibrator element) uniform. For this reason, the gain control circuit 40 which automatically adjusts a gain is provided in an oscillation loop of a drive vibration system. The gain control circuit 40 automatically adjusts the gain variably such that the amplitude (the vibration velocity of the vibrator element) of the feedback signal DG from the angular velocity sensor is uniform. The gain control circuit 40 can be implemented with a full-wave rectifier which full-wave rectifies the output signal DV of the amplification circuit 34, an integrator which performs integration processing of an output signal of a full-wave rectifier, or the like.

The synchronization signal output circuit 52 receives the signal DV after amplification by the amplification circuit 34 and outputs the synchronization signal SYC (reference signal) to the detection circuit 60. The synchronization signal output circuit 52 is implemented with a comparator which performs binarization processing of the sine-wave (AC) signal DV to generate the square-wave synchronization signal SYC, and a phase adjustment circuit (phase shifter) which performs phase adjustment of the synchronization signal SYC, or the like.

The detection circuit 60 (61, 62) includes an amplification circuit 64 and a synchronization detection circuit 81. The amplification circuit 64 receives differential first and second detection signals S1 and S2 from the angular velocity sensor and performs electric charge-voltage conversion, differential signal amplification, gain adjustment, or the like. The synchronization detection circuit 81 performs synchronization detection based on the synchronization signal SYC from the drive circuit 30. Then, an angular velocity signal AV (AVA, AVB) which is a signal of a desired wave is output.

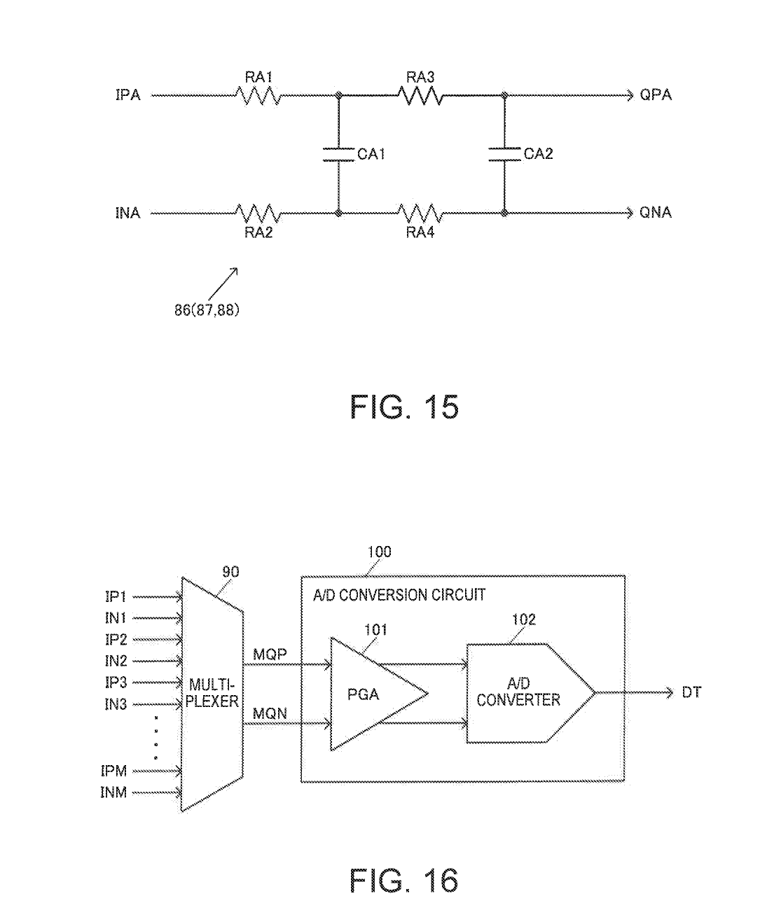

FIG. 15 shows a configuration example of a low-pass filter 86. In FIG. 15, for simplification of description, the configuration of the first and second low-pass filters 87 and 88 is shown as the configuration of the low-pass filter 86.

The low-pass filter 86 includes resistors RA1, RA2, RA3, and RA4 and capacitors CA1 and CA2, and constitutes an RC passive low-pass filter. The low-pass filter 86 receives differential signals IPA and INA as input and outputs differential signals QPA and QNA. The signals IPA and INA are the angular velocity signals (AVA, AVB) which are input from the detection circuit 60 (61, 62), and the signals QPA and QNA are the angular velocity signals (AVA′, AVB′) after the low-pass filter processing which are output to the multiplexer 90. RA1 to RA4 are implemented with, for example, a polyresistor, and CA1 and CA2 are implemented with, for example, a metal-insulator-metal (MIM) capacitor. As described above, since the low-pass filter 86 needs to have a cutoff frequency capable of sufficiently attenuating the frequency component of the detuning frequency, the resistance values of RA1 to RA4 or the capacitance values of CA1 and CA2 become large. Accordingly, the output impedance of the low-pass filter 86 becomes high. From this, in this embodiment, as described referring to FIG. 12, the layout arrangement is made such that the wiring length between the low-pass filter 86 (87, 88) and the multiplexer 90 is shortened. Therefore, it is possible to minimize deterioration of the signal characteristics due to high output impedance of the low-pass filter 86.

FIG. 16 shows a configuration example of the multiplexer 90 and the A/D conversion circuit 100. A plurality of signals IP1, IN1, IP2, IN2, IP3, IN3, . . . , IPM, and INM are input to the multiplexer 90. IP1 and IN1 constitute a pair of differential signals. IP2 and IN2, IP3 and IN3, . . . , and IPM and INM also respectively constitute a pair of differential signals. A signal (differential signal) from the first detection circuit 61 and a signal (differential signal) from the second detection circuit 62 are input to the multiplexer 90 as these signals IP1, IN1, . . . , IPM, and INM. In addition, for example, a signal from a temperature sensor or the like is also input.

Differential output signals MQP and MQN from the multiplexer 90 are input to the A/D conversion circuit 100. The A/D conversion circuit 100 includes a programmable gain amplifier (PGA) 101 and an A/D converter 102. The programmable gain amplifier (PGA) 101 adjusts the gains of the input signals MQP and MQN variably. The A/D converter 102 performs A/D conversion of the analog signals after gain adjustment and outputs the digital signal DT.

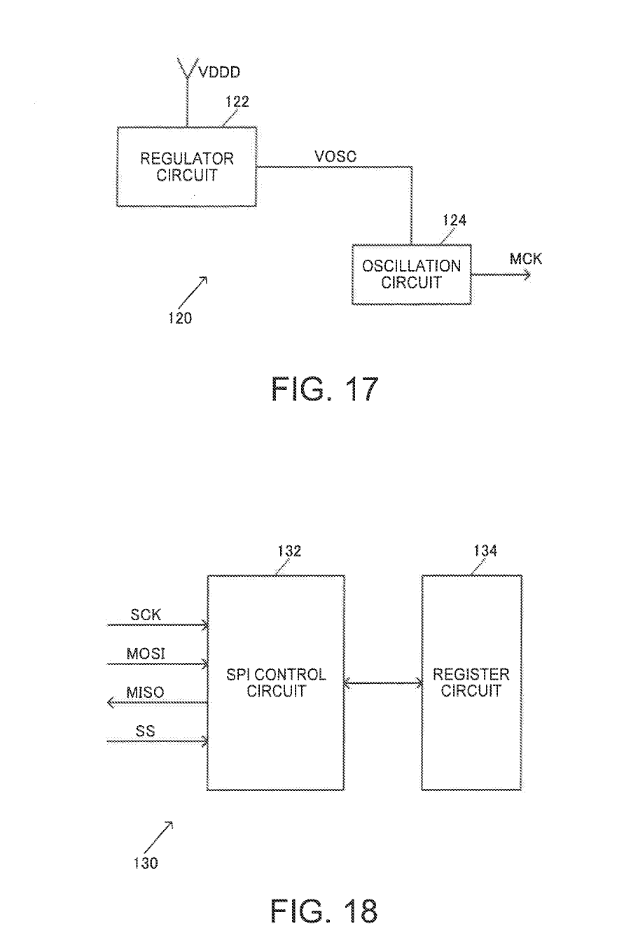

FIG. 17 shows a configuration example of the master clock signal generation circuit 120. The master clock signal generation circuit 120 includes a regulator circuit 122 and an oscillation circuit 124. The regulator circuit 122 performs a regulation operation based on a digital power supply voltage VDDD, generates a constant power supply voltage VOSC, and supplies the power supply voltage VOSC to the oscillation circuit 124. The oscillation circuit 124 performs an oscillation operation with the supply of the power supply voltage VOSC and generates the master clock signal MCK. The oscillation circuit 124 can be implemented with, for example, a multivibrator which oscillates by switching a state between two states. Alternatively, the oscillation circuit 124 may be implemented with a ring oscillator in which an odd number of inverter circuits are connected in a ring shape, a CR oscillation circuit which feeds back an output of each inverter circuit with a CR circuit (a circuit having a capacitor and a resistor), or the like.

FIG. 18 shows a configuration example of the digital I/F circuit 130. FIG. 18 shows a configuration example in a case where the digital I/F circuit 130 is implemented with a SPI system. However, the digital I/F circuit 130 may be implemented with an I2C system or the like.

The digital I/F circuit 130 includes a SPI control circuit 132 and a register circuit 134. To the SPI control circuit 132, a serial clock signal SCK is input from an external device through a serial clock line, reception serial data MOSI is input through a first serial data line, and a slave select signal SS is input through a slave select line. The SPI control circuit 132 outputs transmission serial data MISO to the external device through a second serial data line. Specifically, the SPI control circuit 132 includes a physical layer circuit and a communication processing circuit. For example, the physical layer circuit is an I/O buffer circuit which performs transmission and reception of the serial clock signal SCK, reception serial data MOSI, transmission serial data MISO, and the slave select signal SS. The communication processing circuit is a logic circuit which performs communication processing of SPI communication. For example, the communication processing circuit performs serial-parallel conversion of reception serial data MOSI, command interpretation processing, generation processing of transmission serial data MISO, parallel-serial conversion of transmission serial data MISO, read/write control of the register circuit 134, or the like. In the register circuit 134, information received by the SPI control circuit 132, information transmitted from the SPI control circuit 132, or the like is set.

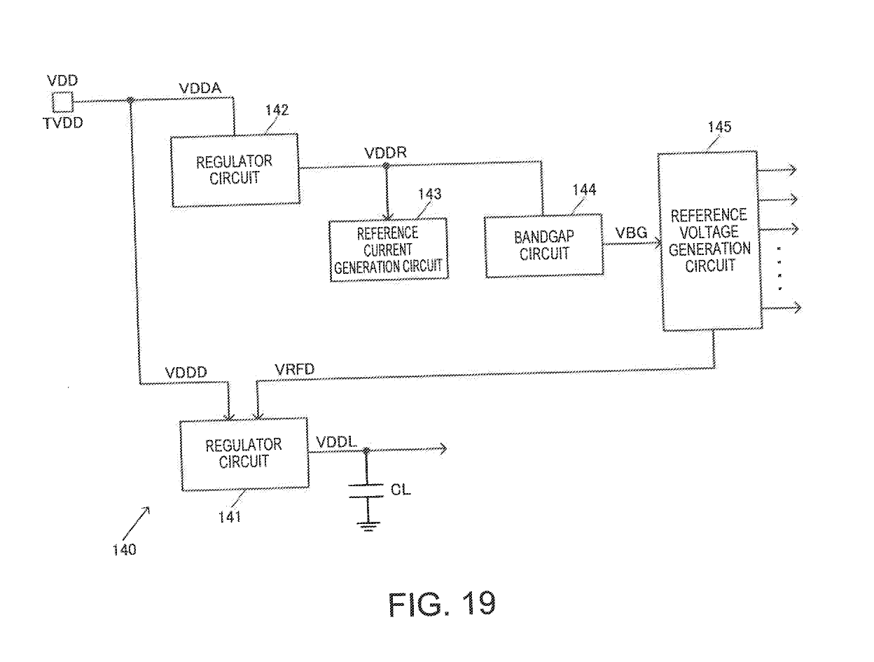

FIG. 19 shows a configuration example of the power supply circuit 140. The power supply circuit 140 includes regulator circuits 141 and 142, a reference current generation circuit 143, a bandgap circuit 144, and a reference voltage generation circuit 145. A power supply voltage VDD from the outside is supplied to a pad (terminal) TVDD. In the circuit device 20, a power line is branched into a first power line and a second power line. An analog power supply voltage VDDA is supplied to the regulator circuit 142 through the first power line. A digital power supply voltage VDDD is supplied to the regulator circuit 141 through the second power line.

The regulator circuit 142 performs a regulation operation based on the analog power supply voltage VDDA and generates a constant power supply voltage VDDR. The reference current generation circuit 143 generates various reference currents when the power supply voltage VDDR is supplied. The generated reference currents are supplied to respective analog circuits of the circuit device 20. The bandgap circuit 144 generates a bandgap reference voltage VBG when the power supply voltage VDDR is supplied. The reference voltage generation circuit 145 generates various reference voltages supplied to the respective circuit blocks of the circuit device 20 based on the bandgap reference voltage VBG. For example, the reference voltage generation circuit 145 generates a reference voltage for a detection circuit, a reference voltage for a drive circuit, a reference voltage for an A/D conversion circuit, or the like.

The regulator circuit 141 performs a regulation operation based on the digital power supply voltage VDDD and generates a constant power supply voltage VDDL. The power supply voltage VDDL is supplied to the logic circuit 110 or the like. As described above, the power supply voltage VDDL is stabilized by the external capacitor CL as an external component.

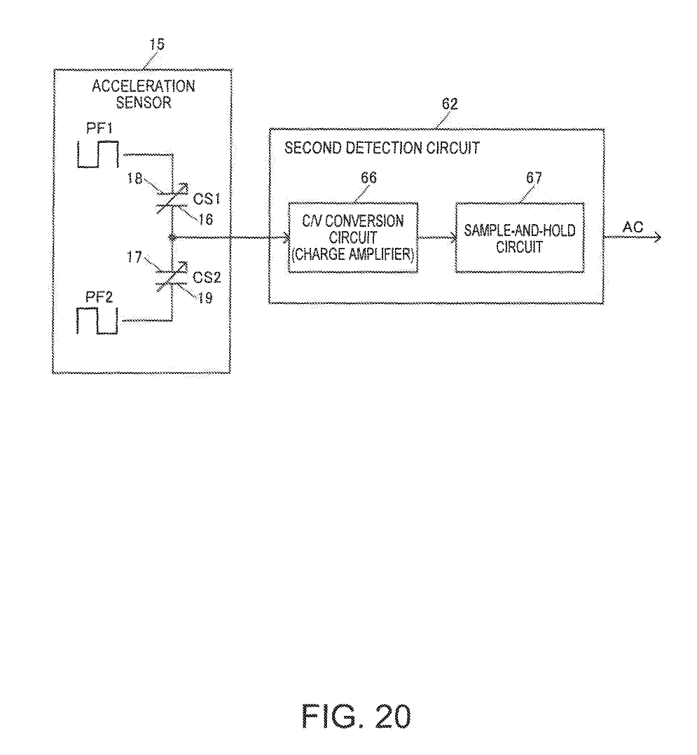

FIG. 20 is a diagram showing a configuration example of an acceleration sensor 15 in a case where the second physical quantity transducer 12 is the acceleration sensor 15 and a configuration example of the second detection circuit 62 for an acceleration sensor.

The acceleration sensor 15 of FIG. 20 is a static capacitance type acceleration sensor. The acceleration sensor 15 includes movable electrodes 16 and 17 and fixed electrodes 18 and 19. The movable electrodes 16 and 17 and the fixed electrodes 18 and 19 are constituted of, for example, a beam structure or the like. Capacitance CS1 is formed by the movable electrode 16 and the fixed electrode 18, and capacitance CS2 is formed by the movable electrode 17 and the fixed electrode 19. A reference signal PF1 (carrier wave) is input to the fixed electrode 18 of the capacitance CS1. A signal PF2 (carrier wave) obtained by inverting the reference signal PF1 with an inverter circuit is input to the fixed electrode 19 of the capacitance CS2. The voltages which are inverted to each other are periodically applied to the fixed electrodes 18 and 19 in this way, whereby it is possible to detect an acceleration based on change in differential capacitance according to the displacement of the movable electrodes 16 and 17.

The second detection circuit 62 includes a C/V conversion circuit 66 (charge amplifier) and a sample-and-hold circuit 67. The C/V conversion circuit 66 is a circuit which converts the above-described change in differential capacitance to a voltage signal, and outputs the obtained voltage signal to the sample-and-hold circuit 67. The C/V conversion circuit 66 can be implemented with, for example, an operational amplifier, a feedback resistor, a feedback capacitor, or the like. The sample-and-hold circuit 67 samples the voltage signal from the C/V conversion circuit 66 and holds the voltage signal for a given period. For example, only a component in a predetermined frequency band is extracted from an output voltage of the sample-and-hold circuit 67, whereby an acceleration signal AC which is the second physical quantity signal is detected. The acceleration sensor 15 is not limited to the static capacitance type of FIG. 20, and various types of acceleration sensors, such as a piezoresistance type or a heat detection type, can be used.

In a case where the acceleration sensor 15 is used as the second physical quantity transducer 12, for example, the acceleration sensor 15 is arranged at the position of the angular velocity sensor 14 of FIG. 4. The acceleration sensor 15 may be, for example, a sensor which can detect accelerations in directions of a plurality of axes, such as a direction of a first axis and a direction of a second axis. In FIG. 4, the angular velocity sensor 13 is arranged above the first detection circuit 61 of the circuit device 20, and the acceleration sensor 15 is arranged above the second detection circuit 62. Even in this case, it is possible to shorten the signal path between the first detection circuit 61 and the angular velocity sensor 13 or the signal path between the second detection circuit 62 and the acceleration sensor 15, and to reduce deterioration of the detection characteristics due to noise or the like.

In a case where the acceleration sensor 15 is used as the second physical quantity transducer 12 in this way, the second drive circuit 32 of the FIG. 11 is not provided. Since the first detection circuit 61 handles a weaker signal than in the second detection circuit 62, the degree of deterioration of the detection characteristics due to noise is large. Accordingly, as shown in FIG. 13, the first detection circuit 61 is arranged in the first area AR1 and the digital I/F circuit 130 or the master clock signal generation circuit 120 is arranged in the second area AR2, whereby it is possible to arrange the digital I/F circuit 130 or the master clock signal generation circuit 120 to be a noise source at a position separated from the first detection circuit 61. As a result, it is possible to effectively reduce deterioration of the detection characteristics of the first detection circuit 61 due to noise from these noise sources.

### 5. Vehicle, Electronic Apparatus

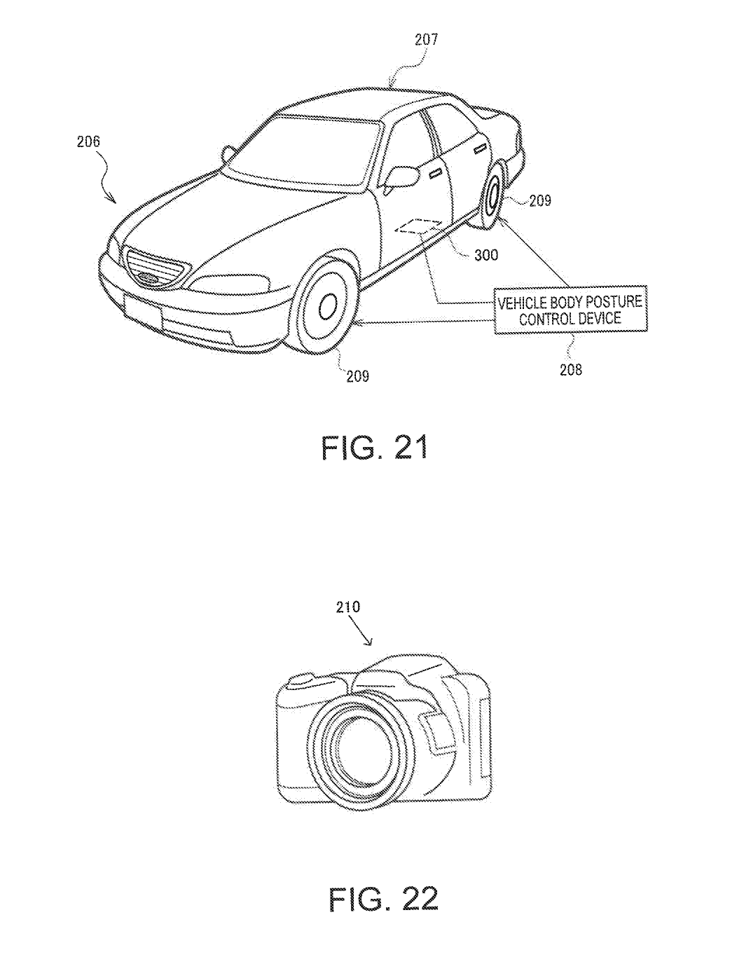

FIGS. 21 to 24 show examples of a vehicle and an electronic apparatus including the circuit device 20 of this embodiment. The circuit device 20 of this embodiment can be incorporated in various vehicles, such as an automobile, an airplane, a motorcycle, a bicycle, and a ship. A vehicle is, for example, equipment or an apparatus which is provided with a drive mechanism, such as an engine or a motor, a steering mechanism, such as a steering wheel or a rudder, and various electronic apparatus and moves on the ground, in the air, or on the sea.

FIG. 21 schematically shows an automobile 206 as a specific example of a vehicle. In the automobile 206, the physical quantity detection device 300 having the first and second physical quantity transducers 11 and 12 and the circuit device 20 is incorporated. The physical quantity detection device 300 (gyro sensor, composite sensor) can detect the posture of a vehicle body 207. A detection signal of the physical quantity detection device 300 is supplied to a vehicle body posture control device 208. The vehicle body posture control device 208 can control hardness of a suspension or can control a brake of each wheel 209 according to the posture of the vehicle body 207. In addition, such posture control can be used in various vehicles, such as a two-legged walking robot, an airplane, and a helicopter. In implementing the posture control, the physical quantity detection device 300 (circuit device 20) is incorporated in a vehicle.

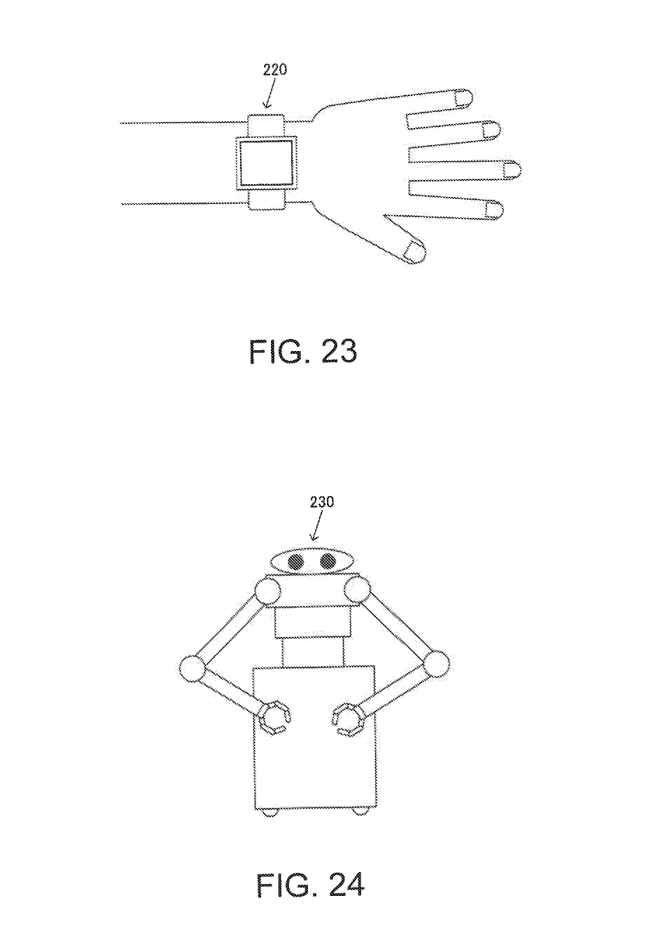

FIGS. 22 and 23 schematically show a digital camera 210 and a biological information detection device 220 as a specific example of an electronic apparatus. In this way, the circuit device 20 of this embodiment can be applied to various electronic apparatuses, such as the digital camera 210 or the biological information detection device 220 (wearable health apparatus, for example, a pulsimeter, a pedometer, an activity meter, or the like). For example, it is possible to perform camera shake correction or the like using a gyro sensor or an acceleration sensor in the digital camera 210. Furthermore, it is possible to detect user's body movement or an operation state using a gyro sensor or an acceleration sensor in the biological information detection device 220.

An electronic apparatus, such as the digital camera 210 or the biological information detection device 220, can include the circuit device 20 of this embodiment, a processing unit, a storage unit, an operating unit, and the like. Furthermore, the electronic apparatus may include a display unit or the like. The storage unit which is implemented with a semiconductor memory (RAM, ROM), an HDD, or the like stores various kinds of information. The processing unit (processor) which is implemented with a CPU, an MPU, or the like performs various kinds of processing based on information stored in the storage unit (memory). The operating unit is provided to allow a user to operate the electronic apparatus, and the display unit displays various kinds of information to the user. As the electronic apparatus, in addition to the digital camera 210 or the biological information detection device 220, various apparatuses, such as a smartphone, a mobile phone, a car navigation system, a game machine, a timepiece, health instrument, and a portable information terminal, can be assumed.

FIG. 24 schematically shows a robot 230 as a specific example of a vehicle or an electronic apparatus. In this way, the circuit device 20 of this embodiment can also be applied to a movable portion (arm, joint) of the robot 230 or a body portion. The robot 230 can be assumed to be a vehicle (traveling or walking robot) or an electronic apparatus (non-traveling or non-walking robot). In a case of a traveling or walking robot, the circuit device 20 of this embodiment can be used for, for example, autonomous traveling.

Although this embodiment has been described above in detail, it can be understood for those skilled in the art that various modifications can be made without substantially departing from the novelty and effects of the invention. Hence, such modification examples are all included in the scope of the invention. For example, in the specification and drawings, the terms (angular velocity sensor, angular velocity sensor/acceleration sensor, angular velocity, angular velocity/acceleration, pad, or the like) described at once with different terms (first physical quantity transducer, second physical quantity transducer, first physical quantity, second physical quantity, terminal, or the like) with broader or the same meaning can be replaced with terms different from those in any place of the specification and drawings. In addition, the configuration of the circuit device, the physical quantity detection device, the electronic apparatus, or the vehicle, the structure of the vibrator element, and the like are also not limited to the devices described in this embodiment, and various modifications can be made for those.

The entire disclosure of Japanese Patent Application No. 2016-061314, filed Mar. 25, 2016 is expressly incorporated by reference herein.

What is claimed is:

1. A circuit device comprising:
a first detection circuit which detects a first physical quantity signal corresponding to a first physical quantity based on a first detection signal from a first physical quantity transducer;
a second detection circuit which detects a second physical quantity signal corresponding to a second physical quantity based on a second detection signal from a second physical quantity transducer;
a multiplexer which selects any one signal among a plurality of signals including the first physical quantity signal from the first detection circuit and the second physical quantity signal from the second detection circuit;
an A/D conversion circuit which performs A/D conversion of the signal selected by the multiplexer to output a digital signal; and
a logic circuit which performs processing of the digital signal from the A/D conversion circuit,
wherein, in a case where a direction along a first side of the circuit device is defined as a first direction and a direction from the first side toward a second side opposite to the first side is defined as a second direction,
the first detection circuit is arranged on the second direction side from the first side,
the second detection circuit is arranged on the second direction side from the first side and on the first direction side from the first detection circuit, and
the A/D conversion circuit is arranged between at least one of the first detection circuit or the second detection circuit and the logic circuit.

2. The circuit device according to claim 1,
wherein the multiplexer is arranged between at least one of the first detection circuit or the second detection circuit and the logic circuit.

3. The circuit device according to claim 1,
wherein, in a case where a direction opposite to the first direction is defined as a third direction,
the A/D conversion circuit is arranged on the third direction side or the first direction side from the multiplexer.

4. The circuit device according to claim 3, further comprising:
a power supply circuit which supplies a power supply voltage,
wherein, in a case where the A/D conversion circuit is arranged on the third direction side from the multiplexer, the power supply circuit is arranged on the first direction side from the multiplexer, and
in a case where the A/D conversion circuit is arranged on the first direction side from the multiplexer, the power supply circuit is arranged on the third direction side from the multiplexer.

5. The circuit device according to claim 1,
wherein, in a case where a direction opposite to the second direction is defined as a fourth direction,
the logic circuit is arranged on the fourth direction side from the second side and on the second direction side from at least one of the first detection circuit or the second detection circuit.

6. The circuit device according to claim 1, further comprising:
a first low-pass filter which performs low-pass filter processing of the first physical quantity signal,
wherein the first low-pass filter is arranged between the first detection circuit and the multiplexer.

7. The circuit device according to claim 6, further comprising:
a second low-pass filter which performs low-pass filter processing of the second physical quantity signal,
wherein the second low-pass filter is arranged between the second detection circuit and the multiplexer.

8. The circuit device according to claim 1,
wherein, in a case where a side intersecting the first side and the second side is defined as a third side, a side intersecting the first side and the second side and opposite to the third side is defined as a fourth side, an area of the circuit device divided by a boundary line parallel to the third side and the fourth side and the third side is defined as a first area, and an area of the circuit device divided by the boundary line and the fourth side is defined as a second area,
the first detection circuit is arranged in the first area, and
the second detection circuit is arranged in the second area.

9. The circuit device according to claim 8, further comprising:
a first drive circuit which drives the first physical quantity transducer,
wherein the first drive circuit is arranged in the first area.

10. The circuit device according to claim 9,
wherein the first drive circuit is arranged between the third side and the logic circuit or between the second side and the logic circuit.

11. The circuit device according to claim 8,
wherein the A/D conversion circuit is arranged in the first area.

12. The circuit device according to claim 8, further comprising:
a master clock signal generation circuit which generates a master clock signal,
wherein the master clock signal generation circuit is arranged in the second area.

13. The circuit device according to claim 1, further comprising:
a digital interface circuit which performs at least one of an input or an output of a digital signal,
wherein the digital interface circuit is arranged between the logic circuit and the second side.

14. The circuit device according to claim 1,
wherein the first physical quantity is an angular velocity around a predetermined axis, and
the second physical quantity is an angular velocity around an axis different from the predetermined axis.

15. The circuit device according to claim 1,
wherein the first physical quantity is an angular velocity, and
the second physical quantity is an acceleration.

16. A physical quantity detection device comprising:
the circuit device according to claim 1;
the first physical quantity transducer; and
the second physical quantity transducer.

17. A physical quantity detection device comprising:
the circuit device according to claim 2;
the first physical quantity transducer; and
the second physical quantity transducer.

18. An electronic apparatus comprising:
the circuit device according to claim 1.

19. An electronic apparatus comprising:
the circuit device according to claim 2.

20. A vehicle comprising:
the circuit device according to claim 1.
